(19) United States
(12) Patent Application Publication
(10) Pub. No.: US 2025/0334881 A1
(43) Pub. Date: Oct. 30, 2025

(54) RADIATION SENSITIVE RESIN COMPOSITION, PATTERN FORMING METHOD, RADIATION SENSITIVE ACID GENERATOR, AND ACID DIFFUSION CONTROL AGENT

(71) Applicant: JSR CORPORATION, Tokyo (JP)

(72) Inventors: Takuhiro TANIGUCHI, Tokyo (JP); Katsuaki NISHIKORI, Tokyo (JP); Natsuko KINOSHITA, Tokyo (JP); Kazuya KIRIYAMA, Tokyo (JP)

(73) Assignee: JSR CORPORATION, Tokyo (JP)

(21) Appl. No.: 18/865,024

(22) PCT Filed: Feb. 22, 2023
(86) PCT No.: PCT/JP2023/006542

§ 371 Date: Nov. 12, 2024

(30) Foreign Application Priority Data
May 20, 2022 (JP) 2022-082729

(51) Int. Cl. G03F 7/039; G03F 7/20

(52) U.S. Cl. CPC G03F 7/0392; G03F 7/2004; G03F 7/2059

(57) ABSTRACT

A radiation sensitive resin composition includes: a resin including a repeating unit A which includes an acid-dissociable group; an onium salt including an organic acid anion moiety and an onium cation moiety; and a solvent. The onium salt includes at least one group selected from the group consisting of a pentafluorosulfanyl group, a pentafluorosulfanyloxy group, and a pentafluorosulfanylthio group.

### TECHNICAL FIELD

The present invention relates to a radiation sensitive resin composition, a pattern forming method, a radiation sensitive acid generator, and an acid diffusion control agent.

### BACKGROUND ART

A photolithography technology has been utilized in which a resist composition is used for the formation of a fine circuit on a semiconductor device. As a representative procedure, for example, a resist pattern is formed on a substrate by generating an acid by irradiating a coating film of the resist composition with radiation through a mask pattern, followed by a reaction in the presence of the acid as a catalyst to generate a difference in solubility of a resin into an alkaline or organic solvent-based developer between an exposed area and an unexposed area.

In the photolithography technology, pattern miniaturization is promoted by using short-wavelength radiation such as from ArF excimer laser or by combining such radiation with an immersion exposure method (liquid immersion lithography). As a next-generation technology, further short-wavelength radiation, such as an electron beam, an X-ray, and an extreme ultraviolet ray (EUV) is being utilized, and a resist material containing an acid generator with a benzene ring having an enhanced efficiency of absorbing such radiation is also being studied (Patent Document 1).

### PRIOR ART DOCUMENT

### Patent Document

Patent Document 1: JP-A-2014-2359

### SUMMARY OF THE INVENTION

### Problems to be Solved by the Invention

Even in the above-described next-generation technology, various resist performances which are equal to or higher than conventional performances are required in terms of LWR performance which is an index of uniformity of a line width together with sensitivity, a width of a process window and the like.

An object of the present invention is to provide a radiation sensitive resin composition, a pattern forming method, a radiation sensitive acid generator, and an acid diffusion control agent capable of exhibiting sensitivity, LWR performance, and a process window at a sufficient level when a next-generation technology is applied.

### Means for Solving the Problems

In order to achieve the object, the present inventors have intensively studied, and as a result have found that the object can be achieved by employing the following features. This finding has led to the completion of the present invention.

The present invention relates to, in one embodiment, a radiation sensitive resin composition including:
a resin containing a repeating unit A having an acid-dissociable group;
an onium salt containing an organic acid anion moiety and an onium cation moiety; and
a solvent;
wherein the onium salt includes at least one group selected from the group consisting of a pentafluorosulfanyl group, a pentafluorosulfanyloxy group, and a pentafluorosulfanylthio group.

According to the radiation sensitive resin composition, a resist film satisfying sensitivity, LWR performance, and a process window can be constructed. The reason for this is not clear, but can be expected as follows. Absorption of radiation such as EUV having a wavelength of 13.5 nm by fluorine atoms is very large, making the radiation sensitive resin composition highly sensitive. In addition, since the acid-dissociable group of the structural unit A in the resin has high acid-dissociation efficiency through exposure to light, the contrast between an exposed area and an unexposed area is so increased that superior pattern-forming performance is exhibited. It is presumed that the resist performance can be exhibited by the combination of these actions.

The present invention relates to, in another embodiment, a pattern forming method including the steps of:
directly or indirectly applying the radiation sensitive resin composition on a substrate to form a resist film;
exposing the resist film to light; and
developing, with a developer, the exposed resist film.

In the pattern forming method, the radiation sensitive resin composition excellent in sensitivity, LWR performance, and process window is used, so that a high-quality resist pattern can be efficiently formed.

Furthermore, the present invention relates to, in another embodiment, a compound including
an onium salt containing an organic acid anion moiety and an onium cation moiety,
wherein the onium salt contains at least one group selected from the group consisting of a pentafluorosulfanyl group, a pentafluorosulfanyloxy group, and a pentafluorosulfanylthio group.

In addition, the present invention relates to, in another embodiment, a radiation sensitive acid generator including a compound including
an onium salt containing an organic acid anion moiety and an onium cation moiety,
wherein the onium salt contains at least one group selected from the group consisting of a pentafluorosulfanyl group, a pentafluorosulfanyloxy group, and a pentafluorosulfanylthio group.

In addition, the present invention relates to, in another embodiment, an acid diffusion control agent including a compound including
an onium salt containing an organic acid anion moiety and an onium cation moiety,
wherein the onium salt contains at least one group selected from the group consisting of a pentafluorosulfanyl group, a pentafluorosulfanyloxy group, and a pentafluorosulfanylthio group.

### MODE FOR CARRYING OUT THE INVENTION

Hereinafter, embodiments of the present invention will be described in detail, but the present invention is not limited to these embodiments.

### <Radiation Sensitive Resin Composition>

A radiation sensitive resin composition (hereinafter also simply referred to as “composition”) according to the present embodiment includes a radiation sensitive resin and a solvent. The composition may contain any other components as long as the effects of the present invention are not impaired. When the radiation sensitive resin composition contains a predetermined resin, the radiation sensitive resin composition can impart sensitivity, LWR performance, and a process window at a high level to a resulting resist film.

### <Resin>

The resin is an aggregate of polymer (G1) containing a repeating unit A having an acid-dissociable group (hereinafter, the polymer (G1) is also referred to as “base resin”). In addition to the repeating unit A, the base resin may contain a repeating unit B containing an organic acid anion moiety and an onium cation moiety, a structural unit D having a phenolic hydroxyl group, a structural unit E containing a lactone structure or the like, and other structural units. Hereinafter, each of the structural units will be described.

### (Repeating Unit A)

The repeating unit A (hereinafter, also referred to as “structural unit A”) is preferably a repeating unit represented by the following formula (1):

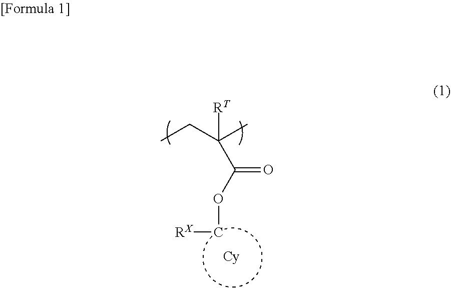

in the formula (1),
R^{T} is a hydrogen atom, a fluorine atom, a methyl group, or a trifluoromethyl group;
R^{X} is a monovalent hydrocarbon group having 1 to 20 carbon atoms; and
Cy represents an alicyclic structure with a 3 to 20 membered ring formed together with a carbon atom to which Cy is bonded.

Examples of the monovalent hydrocarbon group having 1 to 20 carbon atoms represented by R^{X} may include chain hydrocarbon groups having 1 to 10 carbon atoms, monovalent alicyclic hydrocarbon groups having 3 to 20 carbon atoms, and monovalent aromatic hydrocarbon groups having 6 to 20 carbon atoms.

Examples of the chain hydrocarbon group having 1 to 10 carbon atoms may include linear or branched saturated hydrocarbon groups having 1 to 10 carbon atoms, and linear or branched unsaturated hydrocarbon groups having 1 to 10 carbon atoms.

Examples of the alicyclic hydrocarbon group having 3 to 20 carbon atoms may include a monocyclic or polycyclic saturated hydrocarbon group and a monocyclic or polycyclic unsaturated hydrocarbon group. Preferred examples of the monocyclic saturated hydrocarbon groups may include a cyclopentyl group, a cyclohexyl group, a cycloheptyl group, and a cyclooctyl group. As the polycyclic cycloalkyl group, bridged alicyclic hydrocarbon groups such as a norbornyl group, an adamantyl group, a tricyclodecyl group, and a tetracyclododecyl group are preferable. The bridged alicyclic hydrocarbon group refers to a polycyclic alicyclic hydrocarbon group in which two carbon atoms that constitute an alicyclic ring and are not adjacent to each other are bonded by a bonding chain containing one or more carbon atoms.

Examples of the monovalent aromatic hydrocarbon group having 6 to 20 carbon atoms may include aryl groups, such as a phenyl group, a tolyl group, a xylyl group, a naphthyl group, and an anthryl group; and aralkyl groups, such as a benzyl group, a phenethyl group, and a naphthylmethyl group.

As the R^{X}, a linear or branched saturated hydrocarbon group having 1 to 5 carbon atoms, an alicyclic hydrocarbon group having 3 to 12 carbon atoms, and an aromatic hydrocarbon group having 6 to 10 carbon atoms are preferable.

The alicyclic structure having 3 to 20 ring atoms in Cy is not particularly limited as long as it has an alicyclic structure, may have a monocyclic, bicyclic, tricyclic, tetracyclic or more polycyclic structure, and may be any of a bridged ring structure, a spiro ring structure, a ring assembly structure in which a plurality of rings are directly bonded by a single bond or a double bond, or a combination thereof. Among them, it is preferable to have a monocyclic, bicyclic, tricyclic, or tetracyclic bridged ring structure, and it is more preferable to be a ring structure of any of cyclopentane, cyclohexane, norbornane, adamantane, tricyclo[5.2.1.02,6]decane, tetracyclo[4.4.0.12,5.17,10]dodecane, perhydronaphthalene, or perhydroanthracene, or a derivative thereof.

The repeating unit represented by the formula (1) is preferably represented by the following formulas (A-1) to (A-8), for example.

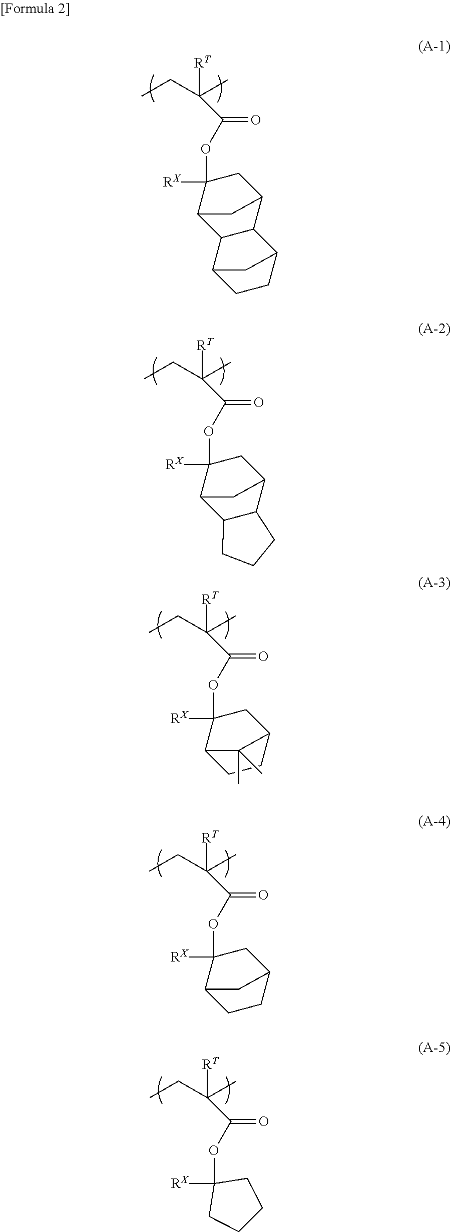

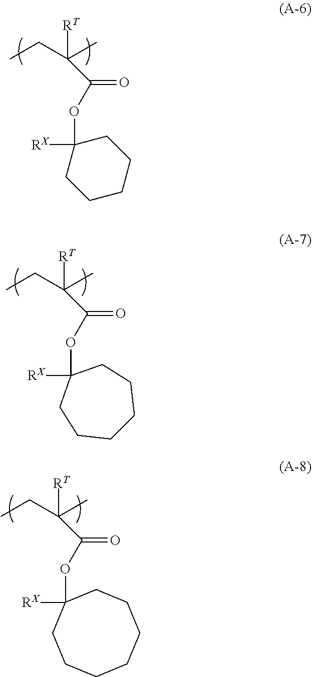

In the formulas (A-1) to (A-8), RT and RX have the same meanings as in the formula (1). Among them, the structural unit A is preferably represented by the formula (A-1), (A-4), (A-5), (A-6), or (A-8), for example.

The structural unit A is also preferably a repeating unit represented by the following formula (1-2):

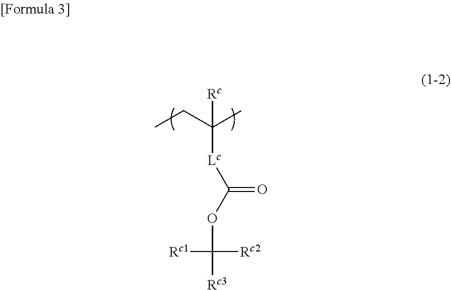

in the formula (1-2),
R^{c} is a hydrogen atom, a fluorine atom, a methyl group, or a trifluoromethyl group; L^{c} is a single bond or a divalent linking group; and R^{c1}, R^{c2} and R^{c3} are each independently a monovalent hydrocarbon group having 1 to 20 carbon atoms.

As R^{c}, a hydrogen atom or a methyl group is preferable from the viewpoint of the copolymerizability of a monomer that affords the structural unit represented by the formula (1-2).

Examples of the divalent linking group represented by L^{c} include an alkanediyl group, a cycloalkanediyl group, an alkenediyl group, —OR^{LA}—*, and —COOR^{LB}—* (* represents a bond on the carbonyl group side).

The alkanediyl group is preferably an alkanediyl group having 1 to 8 carbon atoms.

Examples of the cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propenediyl group, and a butenediyl group. The alkenediyl group is preferably an alkenediyl group having 2 to 6 carbon atoms.

Examples of R^{LA} of —OR^{LA}—* include the alkanediyl group, the cycloalkanediyl group, and the alkenediyl group. Examples of R^{LB} of —COOR^{LB}—* include the alkanediyl group, the cycloalkanediyl group, the alkenediyl group, and an arenediyl group. Examples of the arenediyl group include a benzenediyl group, a tolylene group, and a naphthalenediyl group. The arenediyl group is preferably an arenediyl group having 6 to 15 carbon atoms.

Among them, L^{c} is preferably a single bond or —COOR^{LB}—*. R^{B} is preferably an alkanediyl group.

Some or all of the hydrogen atoms on a carbon atom in L^{c} may be substituted with a halogen atom such as a fluorine atom or a chlorine atom, a halogenated alkyl group such as a trifluoromethyl group, an alkoxy group such as a methoxy group, or a cyano group.

As the monovalent hydrocarbon groups having 1 to 20 carbon atoms represented by R^{c1}, R^{c2}, and R^{c3}, groups represented as monovalent hydrocarbon groups having 1 to 20 carbon atoms represented by RX in the formula (1) and the like can be employed.

Among them, it is preferable that R^{c1} and R^{c2} be each independently a monovalent chain hydrocarbon group having 1 to 10 carbon atoms, and R^{c3} be a monovalent alicyclic or aromatic hydrocarbon group having 6 to 12 carbon atoms.

The repeating unit represented by the formula (1-2) is preferably represented by the following formulas (2-1) to (2-18).

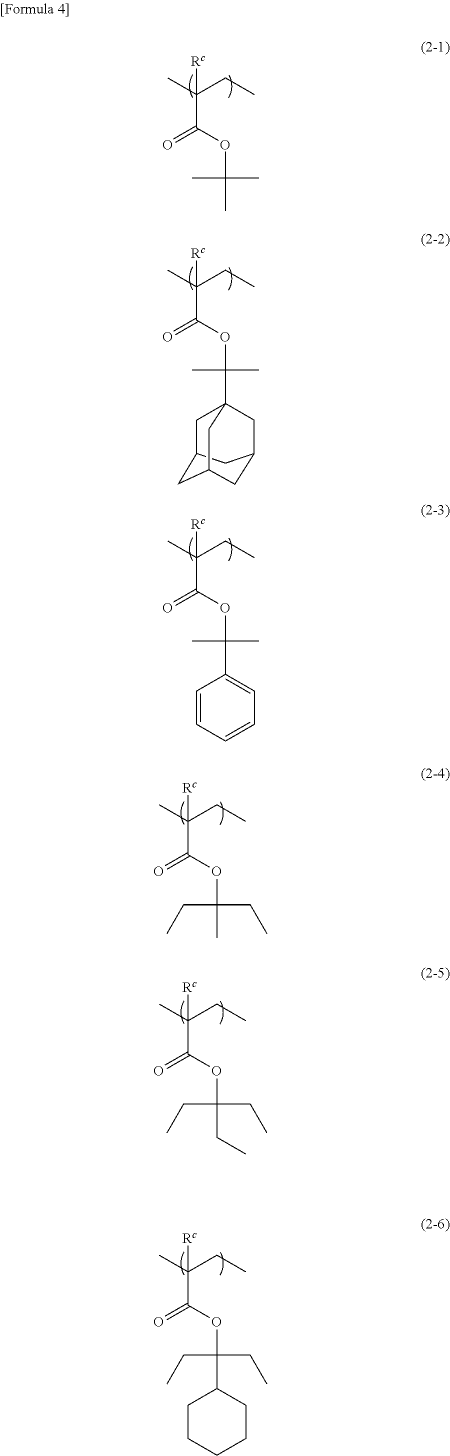

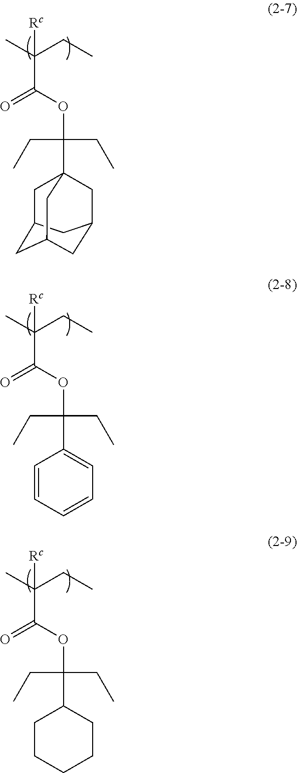

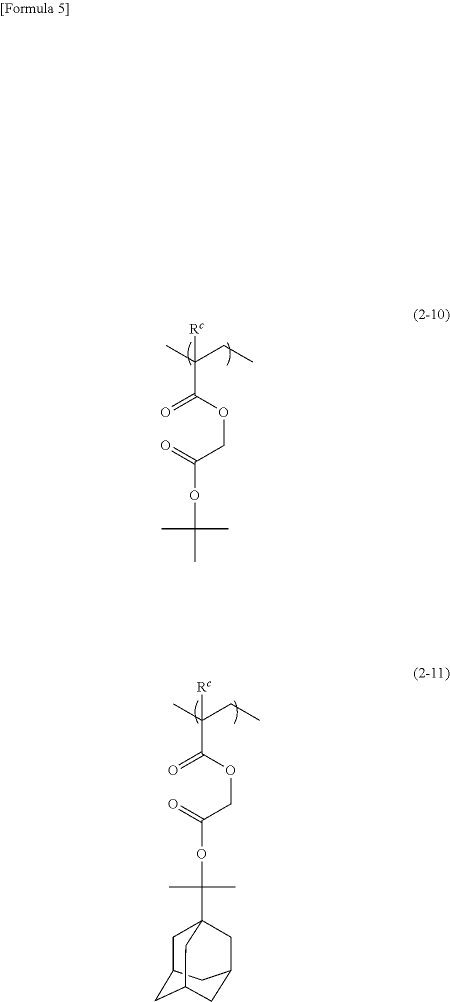

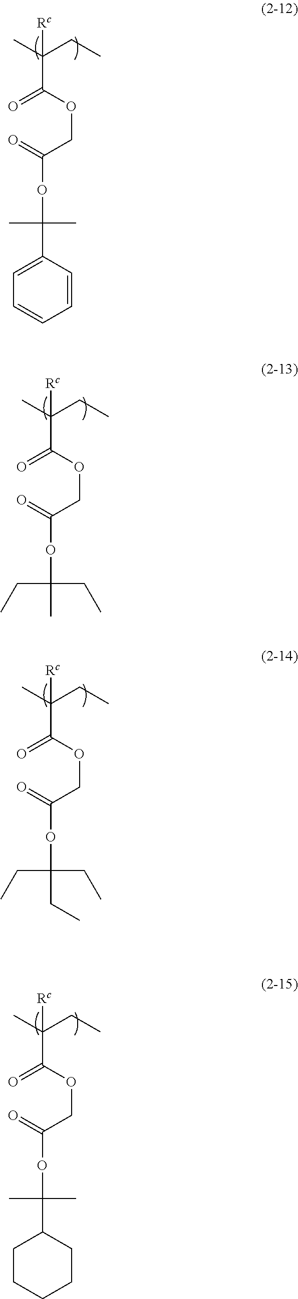

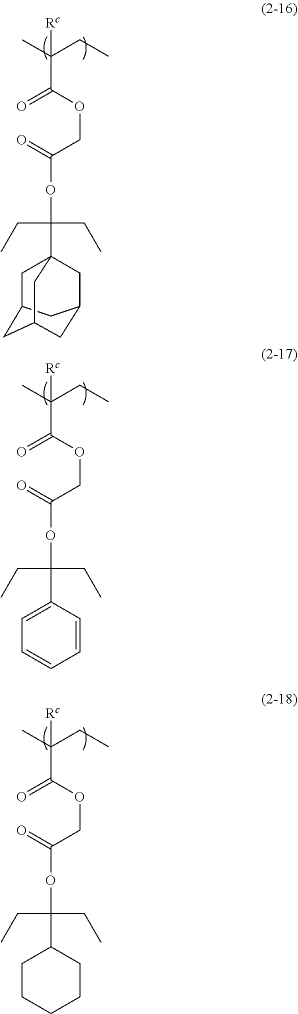

In the formulas (2-1) to (2-18), R^{c} has the same meaning as in the formula (2). Among them, the R^{c} is preferably represented by the formulas (2-1) to (2-3) and (2-10) to (2-12).

The content of the structural unit A in the resin (when there is a plurality of types of structural unit A, the total content thereof is taken) is preferably 10 mol % or more, more preferably 20 mol % or more, still more preferably 30 mol % or more based on all structural units constituting the resin. The content is preferably 80 mol % or less, more preferably 70 mol % or less, still more preferably 60 mol % or less. When the content of the structural unit A is adjusted to within the above range, the sensitivity and LWR performance of the radiation sensitive resin composition can be further improved.

### (Repeating Unit B)

The repeating unit B (hereinafter, also referred to as “structural unit B”) is a repeating unit containing an organic acid anion moiety and an onium cation moiety. Hereinafter, the resin containing the structural unit B is also referred to as “radiation sensitive acid generating resin”.

The structural unit B is a repeating unit derived from a monomer having a structure that is decomposed through exposure to light to generate an acid. Therefore, the resin having the structural unit B functions as a radiation sensitive acid generating resin. Examples of the onium cation moiety in the structural unit B may include a sulfonium cation and an iodonium cation.

The onium cation moiety in the structural unit B is preferably a sulfonium cation, and the monomer to afford such a structural unit B is preferably, for example, a repeating unit derived from a monomer represented by the following formula (2) or a monomer represented by the following formula (3):

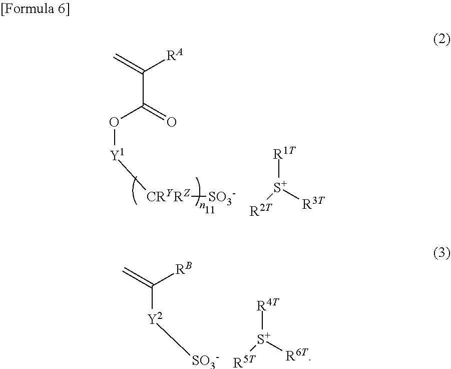

in the formulas (2) and (3),
R^{A} and R^{B} are each a hydrogen atom, a fluorine atom, a methyl group, or a trifluoromethyl group;
R^{Y} and R^{Z} are independently a hydrogen atom, a fluorine atom, or a fluorinated hydrocarbon group, and at least one of R^{Y} and R^{Z} is a fluorine atom or a fluorinated hydrocarbon group; when there are a plurality of R^{Y}s and a plurality of R^{Z}s, they each may be the same or different;
n₁₁ is an integer of 1 to 20;
R^{1T} to R^{3T} are independently a monovalent hydrocarbon group;
R^{4T} to R^{6T} are independently a monovalent hydrocarbon group;
Y¹ is a single bond or —Y¹¹—C(═O)—C—; Y¹¹ is a divalent hydrocarbon group having 1 to 20 carbon atoms optionally containing a heteroatom;
Y² is a single bond, a methylene group, an ethylene group, a phenylene group, a fluorinated phenylene group, —O—Y²¹—, —C(═O)—O—Y²¹—, or —C(═O)—NH—Y²¹—; Y²¹ is an alkanediyl group having 1 to 6 carbon atoms, an alkenediyl group having 2 to 6 carbon atoms, or a phenylene group, and may contain a carbonyl group, an ester linkage, an ether linkage, or a hydroxy group; and the alkanediyl group having 1 to 6 carbon atoms, the alkenediyl group having 2 to 6 carbon atoms, and the phenylene group each may be substituted with a fluorine atom.

In the formulas (2) and (3), R^{Y} and R^{Z} are independently a hydrogen atom, a fluorine atom, or a monovalent fluorinated hydrocarbon group having 1 to 20 carbon atoms, and at least one of R^{Y} and R^{Z} is a fluorine atom or a fluorinated hydrocarbon group. The hydrocarbon group constituting the monovalent fluorinated hydrocarbon group may be linear, branched, or cyclic, and specific examples thereof include alkyl groups such as a methyl group, an ethyl group, an n-propyl group, an isopropyl group, an n-butyl group, and a tert-butyl group; cycloalkyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups such as a vinyl group, an allyl group, a propenyl group, a butenyl group, a hexenyl group, and a cyclohexenyl group; aryl groups such as a phenyl group, a naphthyl group, and a thienyl group; and aralkyl groups such as a benzyl group, a 1-phenylethyl group, and a 2-phenylethyl group. Examples of the monovalent fluorinated hydrocarbon group include those in which some or all of the hydrogen atoms of these hydrocarbon groups are substituted with a fluorine atom-containing group. A plurality of RYs and a plurality of RZs each may be the same or different.

In the formula (2), when Y¹ is —Y¹¹—C(═O)—O—, examples of the divalent hydrocarbon group having 1 to 20 carbon atoms optionally containing a heteroatom represented by Y¹¹ include, but are not limited to, those shown below. Incidentally, any hydrogen atom contained in the structures shown below may be substituted with a substituent containing a hetero atom, and examples of such a substituent include a halogen atom (fluorine atom, chlorine atom, bromine atom, and iodine atom), a carboxy group, a hydroxy group, a thiol group, and an amino group.

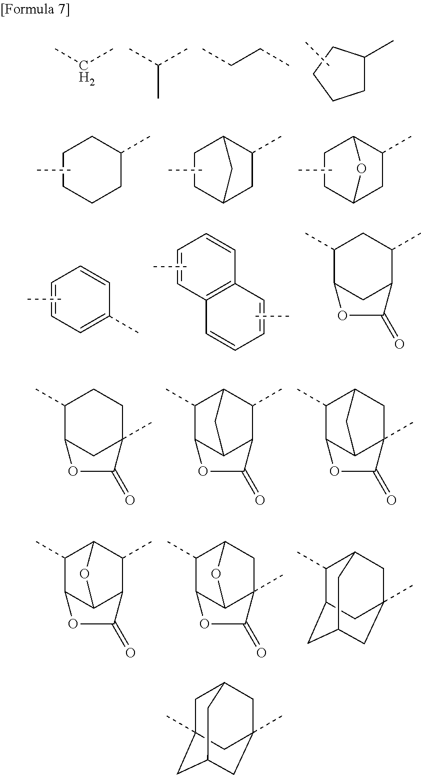

(In the formulas, the broken lines are bonds.)

Examples of the organic acid anion moiety of the monomer that affords the structural unit B include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are substituted with an atom or group other than an iodine atom such as a hydrogen atom or another substituent.

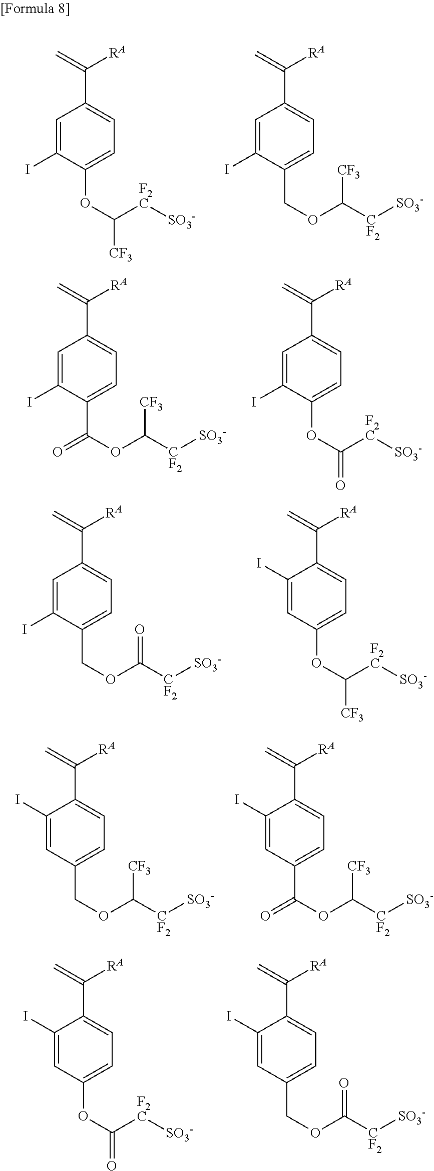

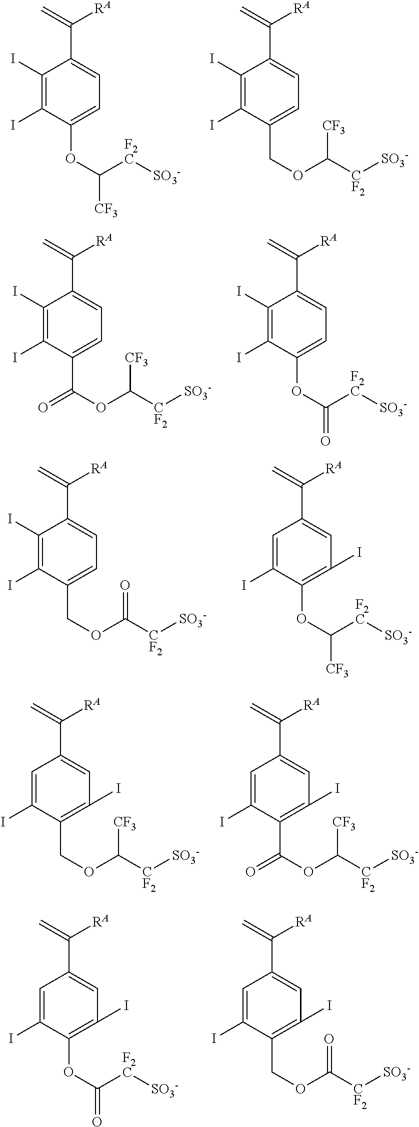

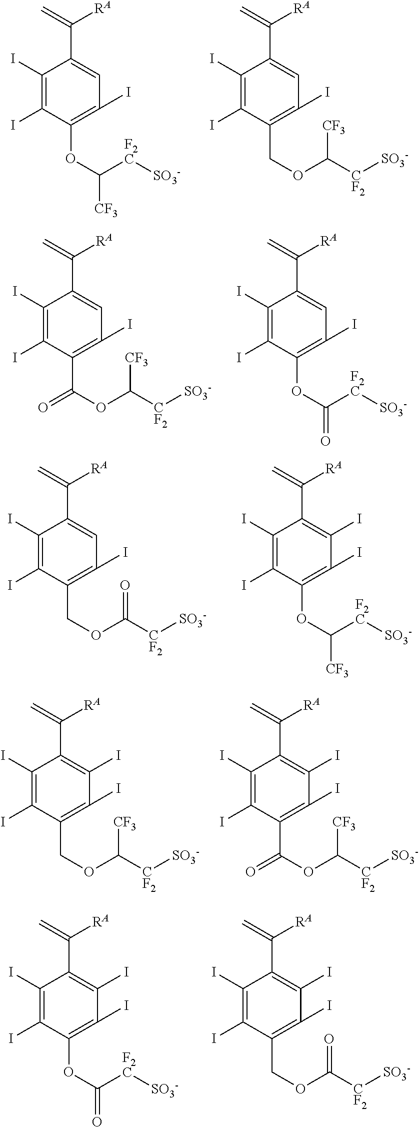

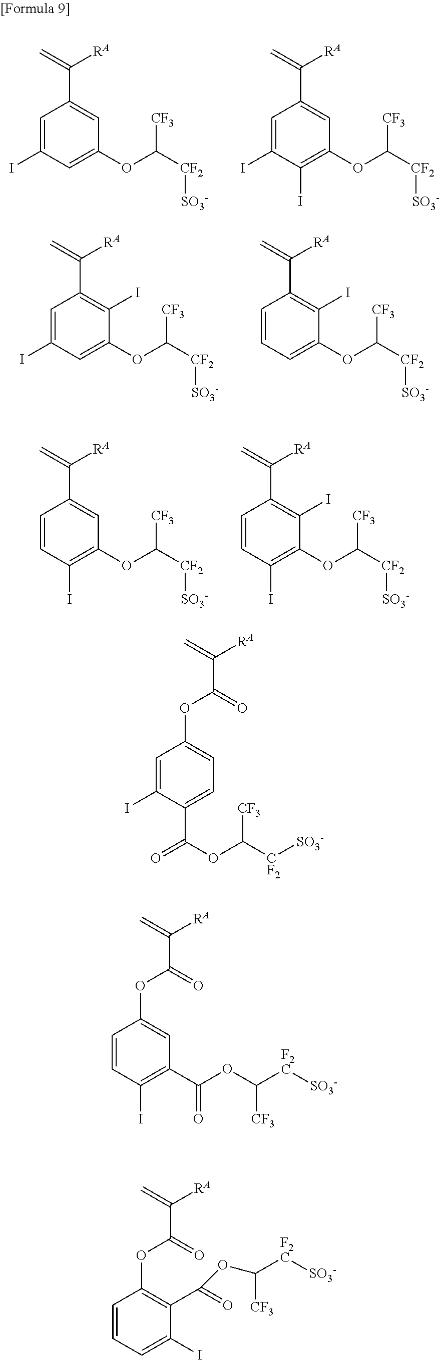

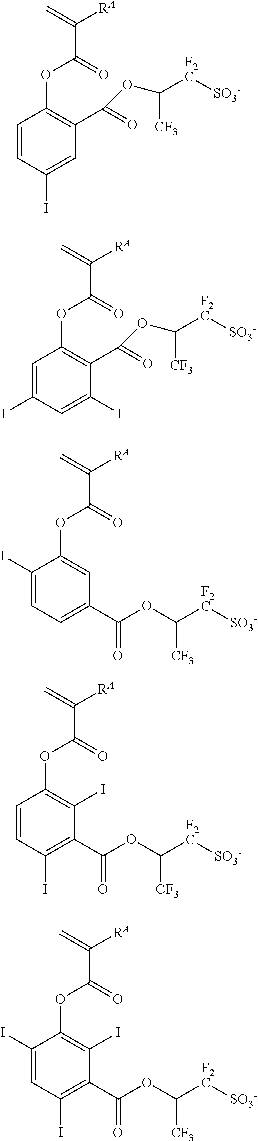

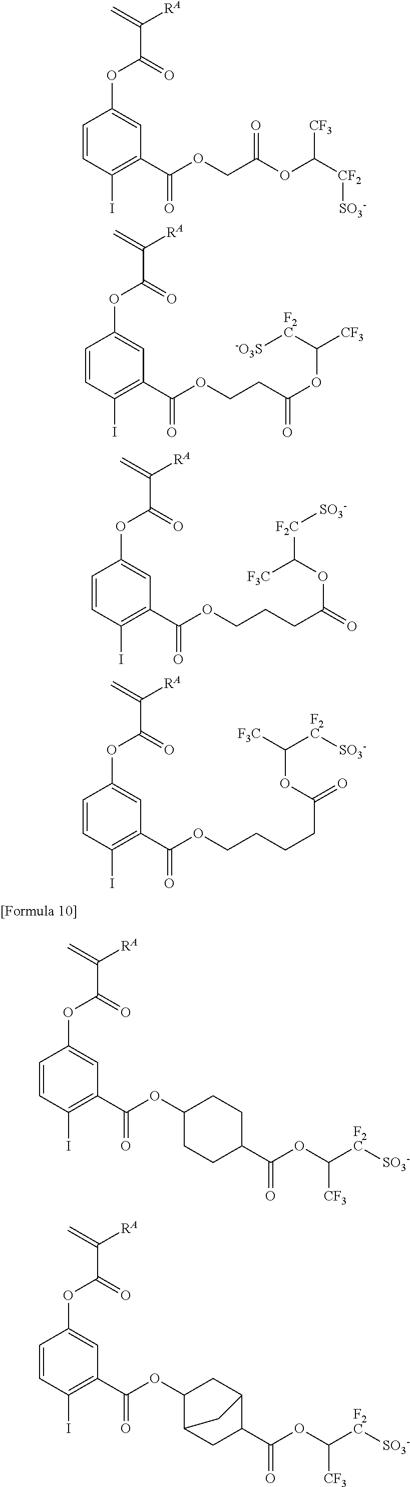

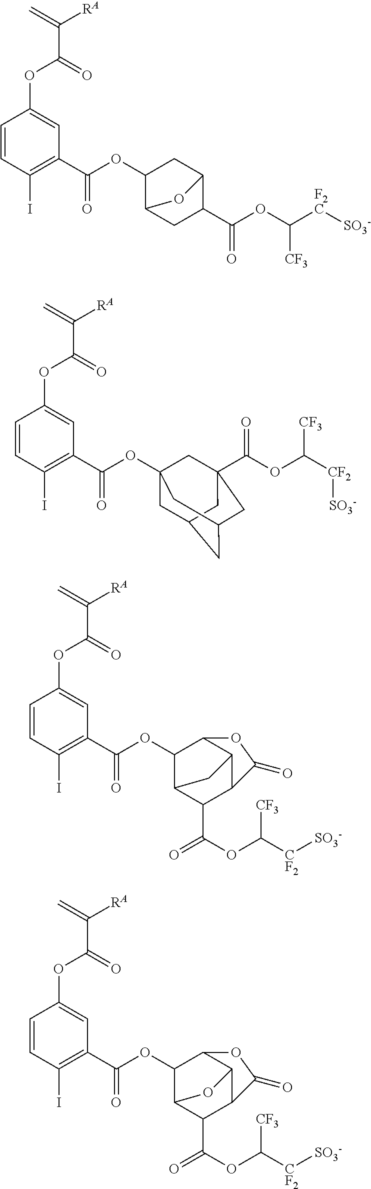

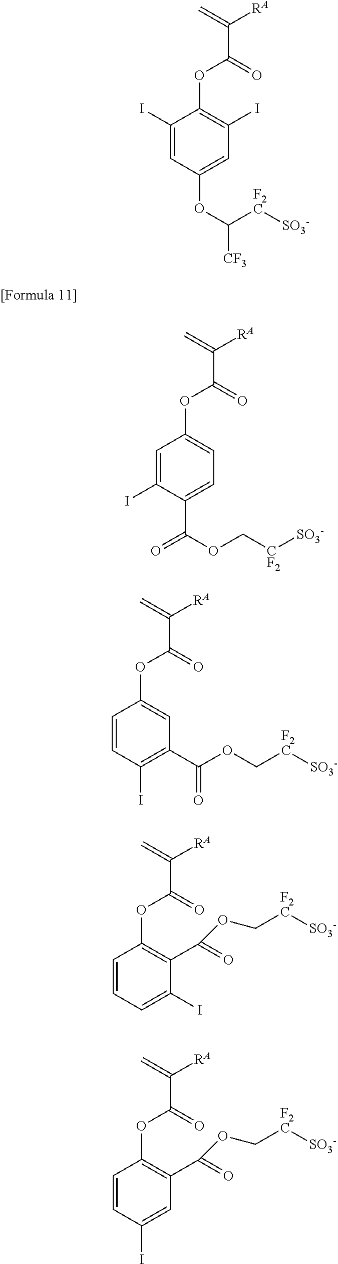

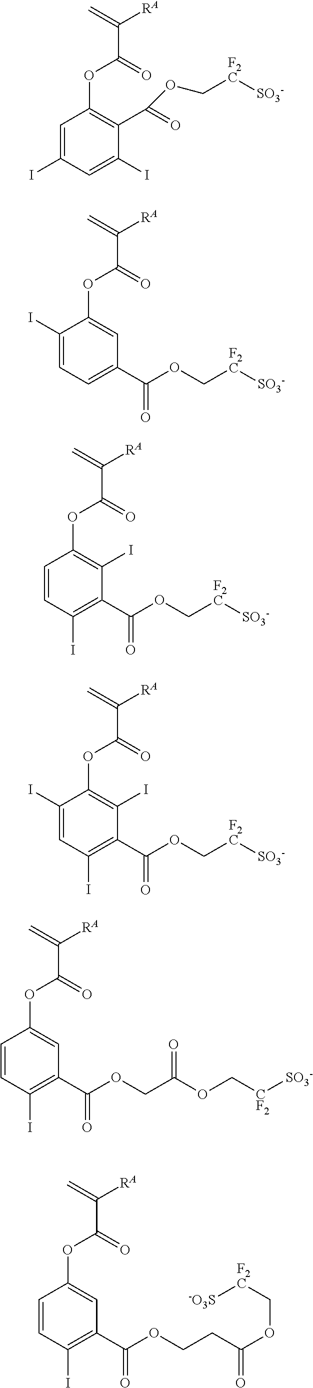

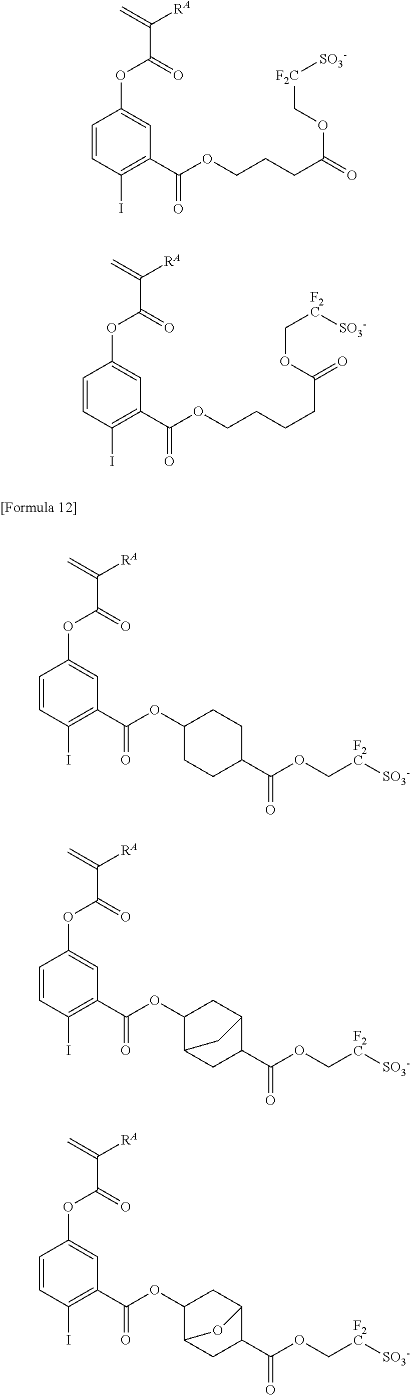

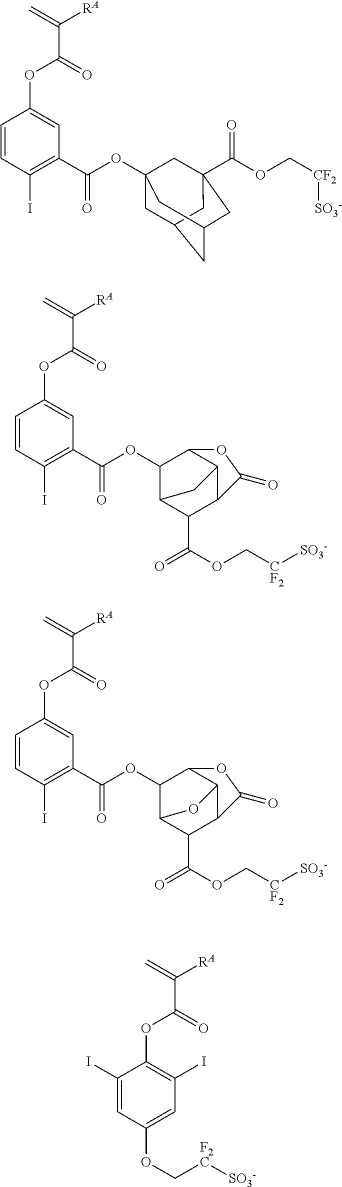

In the formulas (2) and (3), R^{1T} to R^{3T} are independently a monovalent hydrocarbon group, and R^{4T} to R^{6T} are independently a monovalent hydrocarbon group. At least one of the monovalent hydrocarbon groups in R^{1T} to R^{3T} is preferably an aromatic ring having a fluorine atom, and at least one of the monovalent hydrocarbon groups in R^{4T} to R^{6T} is preferably an aromatic ring having a fluorine atom. In the present description, “aromatic ring having a fluorine atom” refers to a structure in which some or all of the hydrogen atoms contained in the aromatic ring are substituted with a fluorine atom, a fluorinated hydrocarbon group (preferably a perfluoro hydrocarbon group), a pentafluorosulfanyl group, a pentafluorosulfanyloxy group, or a pentafluorosulfanylthio group. The monovalent hydrocarbon group may be linear, branched, or cyclic, and specific examples thereof include those the same as those disclosed as examples of the hydrocarbon group constituting the fluorinated hydrocarbon group in RY and RZ, and aryl groups are preferable. Some of the hydrogen atoms of these groups may be substituted with a group containing a heteroatom such as an oxygen atom, a sulfur atom, a nitrogen atom, or a halogen atom. Any two or more of R^{1T} to R^{3T} may be bonded to each other to form a ring together with a sulfur atom to which two or more thereof are bonded, and any two or more of R^{4T} to R^{6T} may be bonded to each other to form a ring together with a sulfur atom to which two or more thereof are bonded.

The onium cation moiety in the formulas (2) and (3) is preferably represented by the following formula (Q-1).

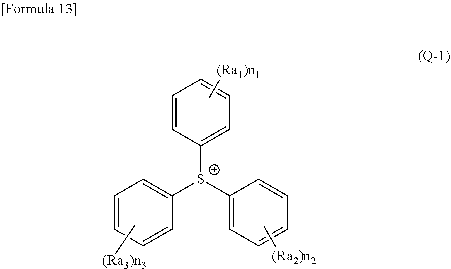

In the formula (Q-1), Ra₁ and Ra₂ each independently represent a substituent. n₁ represents an integer of 0 to 5, and when n₁ is 2 or more, the plurality of Ra₁s may be the same as or different from each other. n₂ represents an integer of 0 to 5, and when n₂ is 2 or more, the plurality of Ra₂s may be the same as or different from each other. n₃ represents an integer of 1 to 5, and when n₃ is 2 or more, the plurality of Ra₃s may be the same as or different from each other. Ra₃ represents a substituent. Ra₁ and Ra₂ may be linked to each other to form a ring. When n₁ is 2 or more, the plurality of Ra₁s may be linked to each other to form a ring. When n₂ is 2 or more, the plurality of Ra₂s may be linked to each other to form a ring. When n₁ is 1 or more and n₂ is 1 or more, Ra₁ and Ra₂ may be linked to each other to form a ring (namely, a heterocyclic ring containing a sulfur atom).

The substituent represented by Ra₁ and Ra₂ is preferably an alkyl group, a cycloalkyl group, an alkoxy group, a cycloalkyloxy group, an alkoxycarbonyl group, an alkylsulfonyl group, a hydroxyl group, a halogen atom, a halogenated hydrocarbon group, a pentafluorosulfanyl group, a pentafluorosulfanyloxy group, or a pentafluorosulfanylthio group.

The alkyl group as Ra₁ and Ra₂ may be either linear or branched. As the alkyl group, those having 1 to 10 carbon atoms are preferable, and examples thereof include those the same as those disclosed as examples of the hydrocarbon group constituting the fluorinated hydrocarbon group in R^{Y} and R^{Z}. Among them, a methyl group, an ethyl group, an n-butyl group, and a t-butyl group are particularly preferable.

Examples of the cycloalkyl group as Ra₁ and Ra₂ include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among them, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra₁ and Ra₂ include those listed above as the alkyl groups as Ra₁ and Ra₂. As the alkoxy group, a methoxy group, an ethoxy group, an n-propoxy group, and an n-butoxy group are particularly preferable.

Examples of the cycloalkyl group moiety of the cycloalkyloxy group as Ra₁ and Ra₂ include those listed above as the cycloalkyl groups as Ra₁ and Ra₂. As the cycloalkyloxy group, a cyclopentyloxy group and a cyclohexyloxy group are particularly preferable.

Examples of the alkoxy group moiety of the alkoxycarbonyl group as Ra₁ and Ra₂ include those listed above as the alkoxy groups as Ra₁ and Ra₂. As the alkoxycarbonyl group, a methoxycarbonyl group, an ethoxycarbonyl group, and an n-butoxycarbonyl group are particularly preferable.

Examples of the alkyl group moiety of the alkylsulfonyl group as Ra₁ and Ra₂ include those listed above as the alkyl groups as Ra₁ and Ra₂. Examples of the cycloalkyl group moiety of the cycloalkylsulfonyl group as Ra₁ and Ra₂ include those listed above as the cycloalkyl groups as Ra₁ and Ra₂. As the alkylsulfonyl group or the cycloalkylsulfonyl group, a methanesulfonyl group, an ethanesulfonyl group, an n-propanesulfonyl group, an n-butanesulfonyl group, a cyclopentanesulfonyl group, and a cyclohexanesulfonyl group are particularly preferable.

Each of the groups Ra₁ and Ra₂ may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra₁ and Ra₂ include a fluorine atom, a chlorine atom, a bromine atom, and an iodine atom, and a fluorine atom is preferable.

As the halogenated hydrocarbon group as Ra₁ and Ra₂, a halogenated alkyl group is preferable. Examples of the alkyl group and the halogen atom constituting the halogenated alkyl group include those the same as those described above. Among them, fluorinated alkyl groups are preferable, and CF₃ is more preferable.

As described above, Ra₁ and Ra₂ may be linked to each other to form a ring (namely, a heterocyclic ring containing a sulfur atom). In this case, it is preferable that Ra₁ and Ra₂ be bonded to each other to form a single bond or a divalent linking group. Examples of the divalent linking group include —COO—, —OCO—, —CO—, —C—, —S—, —SO—, —SO₂—, an alkylene group, a cycloalkylene group, an alkenylene group, and combinations of two or more thereof, and those having 20 or less carbon atoms in total are preferable. When Ra₁ and Ra₂ are linked to each other to form a ring, it is preferable that Ra₁ and Ra₂ be bonded to each other to form —COO—, —OCO—, —CO—, —C—, —S—, —SO—, —SO2-, or a single bond. Among them, it is more preferable to form —C—, —S—, or a single bond, and it is particularly preferable to form a single bond. When n₁ is 2 or more, the plurality of Ra₁s may be linked to each other to form a ring, and when n₂ is 2 or more, the plurality of Ra₂s may be linked to each other to form a ring. Examples thereof include an aspect in which two Ra₁s are linked to each other to form a naphthalene ring together with a benzene ring to which two Ra₁s are bonded.

The substituent represented by Ra₃ is preferably an alkyl group, a cycloalkyl group, an alkoxy group, a cycloalkyloxy group, an alkoxycarbonyl group, an alkylsulfonyl group, a hydroxyl group, a halogen atom, a halogenated hydrocarbon group, a pentafluorosulfanyl group, a pentafluorosulfanyloxy group, or a pentafluorosulfanylthio group. Among them, at least one or more Ra₃ is preferably a fluorine atom or a group having one or more fluorine atoms, and at least one or more Ra₃ is more preferably a pentafluorosulfanyl group, a pentafluorosulfanyloxy group, or a pentafluorosulfanylthio group. Examples of the group having a fluorine atom may include groups in which the alkyl group, the cycloalkyl group, the alkoxy group, the cycloalkyloxy group, the alkoxycarbonyl group, and the alkylsulfonyl group as Ra₁ and Ra₂ are substituted with a fluorine atom. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra₃ is preferably a fluorine atom, CF₃, a pentafluorosulfanyl group, a pentafluorosulfanyloxy group, or a pentafluorosulfanylthio group.

n₁ and n₂ are each independently preferably an integer of 0 to 3, preferably an integer of 0 to 2.

n₃ is preferably an integer of 1 to 3, more preferably 1 or 2.

(n₁+n₂+n₃) is preferably an integer of 1 to 15, more preferably an integer of 1 to 9, still more preferably an integer of 2 to 6, particularly preferably an integer of 3 to 6.

Specific examples of such an onium cation moiety represented by the formula (Q-1) include the onium cation in the onium salt described later.

As the onium cation moiety in the structural unit B, a diaryliodonium cation is also preferable.

Specific examples of such a diaryliodonium cation include those shown below. While all of those shown below are iodonium cation moieties including an aromatic ring structure having a fluorine atom, a structure in which a fluorine atom is substituted with a fluorinated hydrocarbon group such as a trifluoromethyl group or a structure in which a fluorine atom is substituted with a hydrogen atom can also be suitably employed.

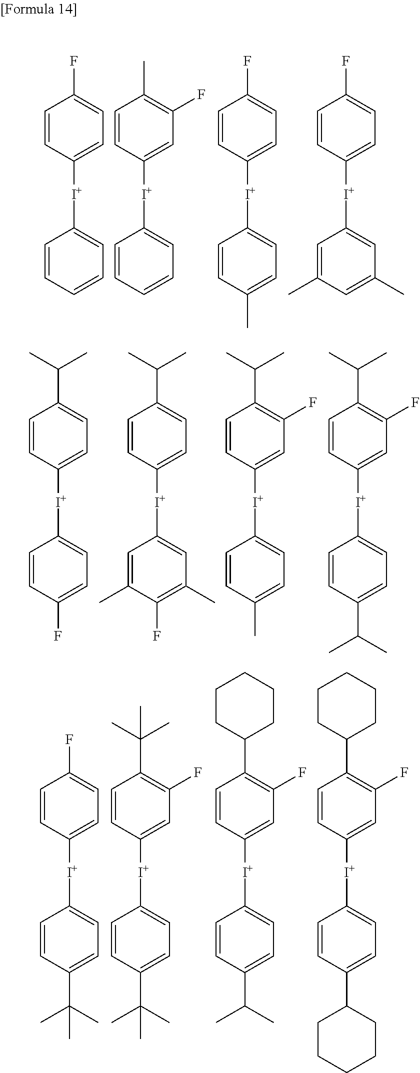

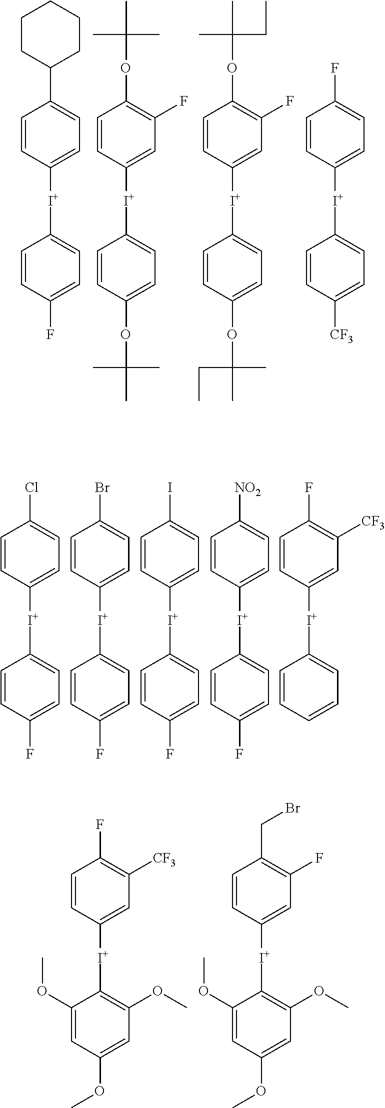

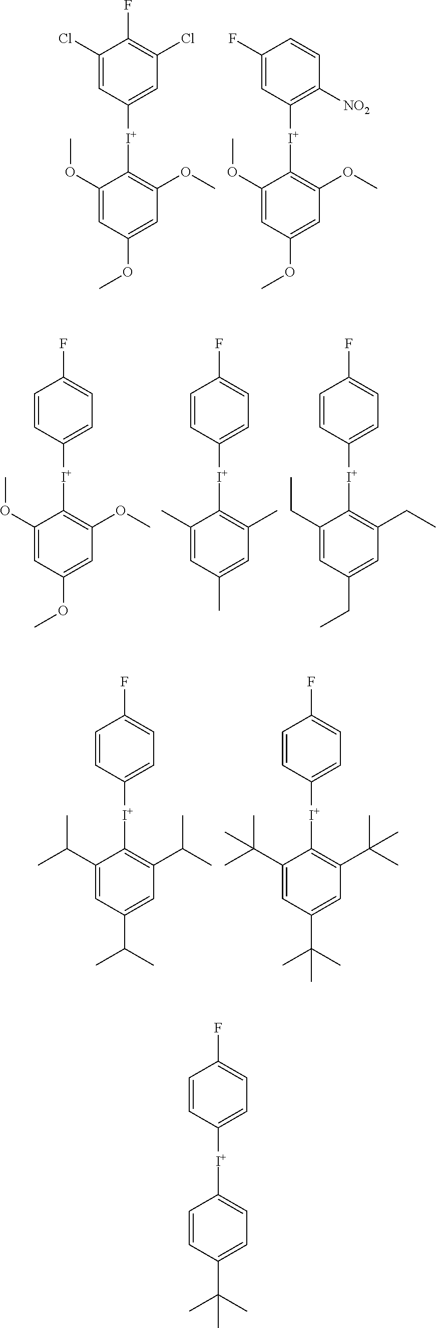

The content of the structural unit B in the resin (when there is a plurality of types of structural unit C, the total content thereof is taken) is preferably 2 mol % or more, more preferably 3 mol % or more, still more preferably 4 mol % or more, particularly preferably 5 mol % or more based on all structural units constituting the resin. The content is preferably 30 mol % or less, more preferably 25 mol % or less, still more preferably 20 mol % or less, particularly preferably 15 mol % or less. When the content is adjusted to within the above range, the function as an acid generator can be sufficiently exhibited.

### (Repeating Unit D)

The repeating unit D (hereinafter, also referred to as “structural unit D”) is a structural unit having a phenolic hydroxyl group. In the present invention, a phenolic hydroxy group generated through deprotection by the action of an acid generated through exposure to light is also included as the phenolic hydroxy group of the structural unit D. When the resin contains the structural unit D, the solubility in a developer can be more appropriately adjusted, and as a result, the sensitivity and the like of the radiation sensitive resin composition can be further improved. When KrF excimer laser light, EUV, electron beam or the like is used as radiation applied in an exposure step in a method for forming a resist pattern, the structural unit D contributes to improvement in etching resistance and improvement in difference in solubility in a developer (dissolution contrast) between an exposed area and an unexposed area. In particular, the resin containing the structural unit D can be suitably applied for pattern formation performed using exposure to radiation having a wavelength of 50 nm or less such as electron beam or EUV. The structural unit D is preferably a repeating unit represented by the following formula (D):

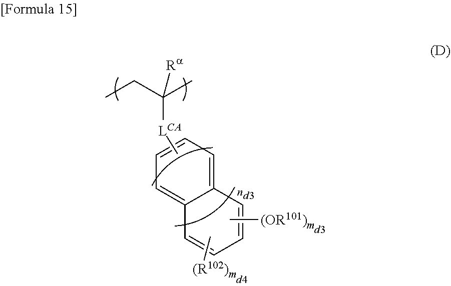

In the formula (D),
R^{α} is a hydrogen atom, a fluorine atom, a methyl group, or a trifluoromethyl group.

L^{CA} is a single bond, —COO—*, or —O—. * is a bond on the aromatic ring side.

R¹⁰¹ is a hydrogen atom or a protective group that is deprotected by the action of an acid. When there are a plurality of R¹⁰¹s, the plurality of R¹⁰¹s are the same as or different from each other.

R¹⁰² is a cyano group, a nitro group, an alkyl group, a fluorinated alkyl group, an alkoxycarbonyloxy group, an acyl group, or an acyloxy group.

n_{d3} is an integer of 0 to 2, m_{3d} is an integer of 1 to 8, and m_{d4} is an integer of 1 to 8, provided that 1≤m_{d3}+m_{d4}≤2n_{d3}+5 is satisfied.

The R^{α} is preferably a hydrogen atom or a methyl group from the viewpoint of the copolymerizability of a monomer that affords the structural unit D.

The LCA is preferably a single bond or —COO—*.

Examples of the protective group that is deprotected by the action of the acid represented by R¹⁰¹ may include groups represented by the following formulas (AL-1) to (AL-3).

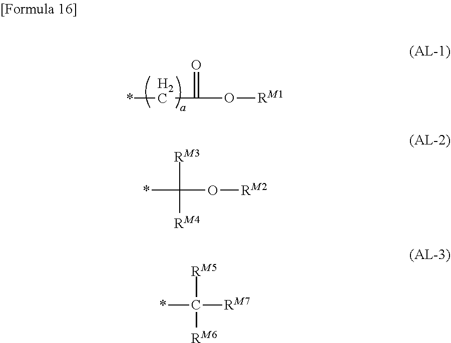

In the formulas (AL-1) and (AL-2), R^{M1} and R^{M2} are monovalent hydrocarbon groups, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, more preferably an alkyl group having 1 to 20 carbon atoms. In the formula (AL-1), a is an integer of 0 to 10, preferably an integer of 1 to 5. In the formulas (AL-1) to (AL-3), * is a bond to another moiety.

In the formula (AL-2), R^{M3} and R^{M4} are each independently a hydrogen atom or a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M2}, R^{M3}, and R^{M4} may be bonded to each other to form a ring having 3 to 20 carbon atoms together with a carbon atom or a carbon atom and an oxygen atom to which two thereof are bonded. The ring is preferably a ring having 4 to 16 carbon atoms, particularly preferably an alicyclic ring.

In the formula (AL-3), R^{M5}, R^{M6}, and R^{M7} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M5}, R^{M6}, and R^{M7} may be bonded to each other to form a ring having 3 to 20 carbon atoms together with a carbon atom to which two thereof are bonded. The ring is preferably a ring having 5 to 16 carbon atoms, particularly preferably an alicyclic ring.

Among them, the protective group that is deprotected by the action of an acid is preferably a group represented by the formula (AL-3).

Examples of the alkyl group in R¹⁰² may include linear or branched alkyl groups having 1 to 8 carbon atoms such as a methyl group, an ethyl group, and a propyl group. Examples of the fluorinated alkyl group may include linear or branched fluorinated alkyl groups having 1 to 8 carbon atoms such as a trifluoromethyl group and a pentafluoroethyl group. Examples of the alkoxycarbonyloxy group may include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group may include aliphatic or aromatic acyl groups having 2 to 12 carbon atoms such as an acetyl group, a propionyl group, a benzoyl group, and an acryloyl group. Examples of the acyloxy group may include aliphatic or aromatic acyloxy groups having 2 to 12 carbon atoms such as an acetyloxy group, a propionyloxy group, a benzoyloxy group, and an acryloyloxy group.

The n_{d3} is preferably 0 or 1, more preferably 0.

The m_{d3} is preferably an integer of 1 to 3, more preferably 1 or 2.

The m_{d4} is preferably an integer of 0 to 3, more preferably an integer of 0 to 2.

As the structural unit D, structural units represented by the following formulas (D-1) to (D-10) (hereinafter, also referred to as “structural units (D-1) to (D-10)”) and the like are preferable.

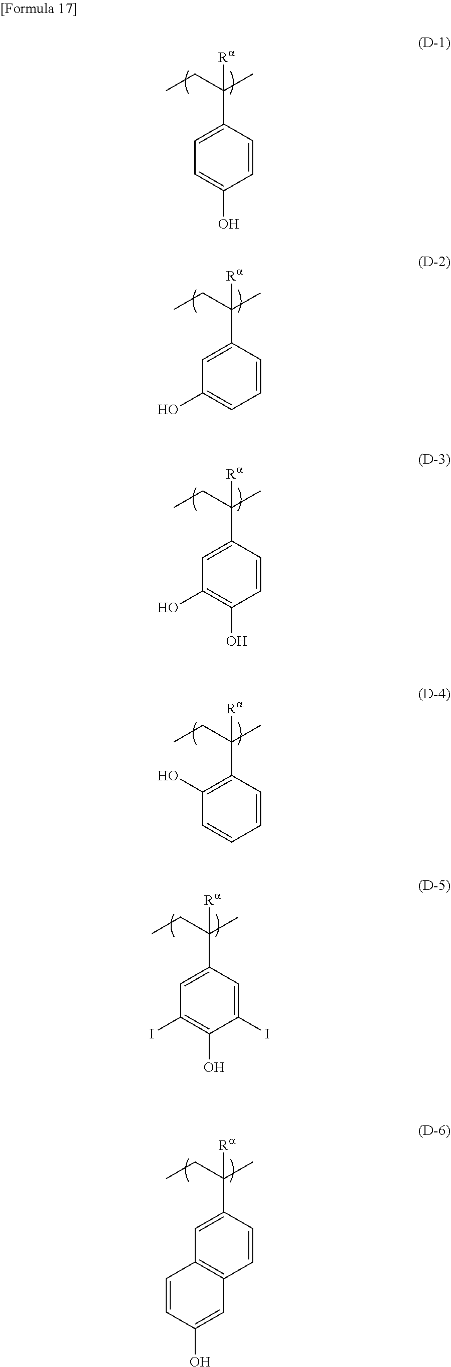

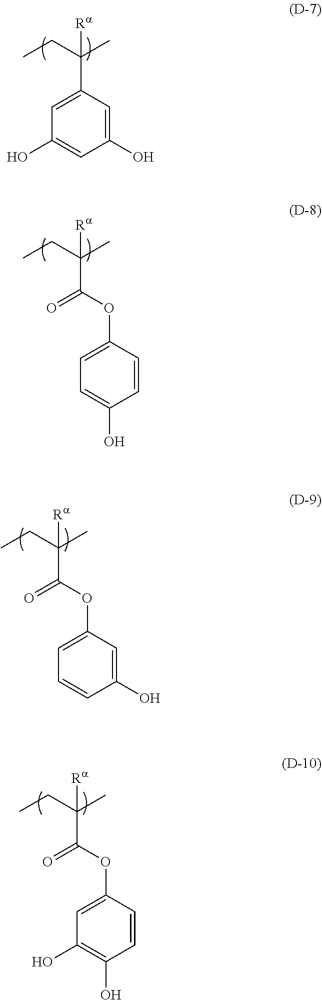

In the formulas (D-1) to (D-10), Ra is the same as in the above formula (D).

Among them, the structural units (D-1) to (D-5) and (D-7) to (D-10) are preferable.

The content of the structural unit D (when there is a plurality of types of structural unit D, the total content thereof is taken) is preferably 5 mol % or more, more preferably 8 mol % or more, still more preferably 10 mol % or more, particularly preferably 15 mol % or more based on all structural units constituting the resin. The content is preferably 60 mol % or less, more preferably 50 mol % or less, still more preferably 40 mol % or less. When the content of the structural unit D is adjusted to within the above range, the sensitivity, LWR performance, and process window of the radiation sensitive resin composition can be further improved.

### (Structural Unit E)

The structural unit E is a structural unit containing at least one structure selected from the group consisting of a lactone structure, a cyclic carbonate structure, and a sultone structure. When the base resin further has the structural unit E, the solubility in a developer can be adjusted, and as a result, the lithographic performance, such as resolution, of the radiation sensitive resin composition can be improved. In addition, the adhesion between a resist pattern formed of the base resin and a substrate can be improved.

The content of the structural unit E is preferably 5 mol % or more, more preferably 10 mol % or more, still more preferably 20 mol % or more based on all structural units constituting the base resin. The content is preferably 60 mol % or less, more preferably 50 mol % or less, still more preferably 40 mol % or less. When the content of the structural unit E is adjusted to within the above range, the lithographic performance, such as resolution, of the radiation sensitive resin composition and the adhesion between a formed resist pattern and a substrate can be further improved.

The base resin of the present invention may contain a structural unit other than the structural units A, B, D, and E. Examples of such another structural unit may include a structural unit having an aliphatic hydrocarbon group (excluding the structural unit A) such as alkyl (meth)acrylate; a structural unit having an alicyclic hydrocarbon group (excluding the structural unit A) such as cycloalkyl (meth)acrylate or adamantyl (meth)acrylate; and a structural unit having an aromatic hydrocarbon group such as styrene, phenyl (meth)acrylate, or iodostyrene.

The base resin of the present invention preferably contains an iodine-substituted aromatic ring structure. The iodine-substituted aromatic ring structure of the base resin is preferably contained in the structural unit A, B, D, or E or a structural unit other than A to E, more preferably contained in the structural unit B or D or a structural unit other than A to E. The content of the iodine-substituted aromatic ring structure is preferably 1 mol % or more, more preferably 2 mol % or more, still more preferably 3 mol % or more based on all structural units constituting the base resin. The content is preferably 30 mol % or less, more preferably 25 mol % or less, still more preferably 20 mol % or less. When the content of the iodine-substituted aromatic ring structure is adjusted to within the above range, the radiation sensitive resin composition can further improve the lithographic performance such as LWR performance.

### (Method for Synthesizing Resin)

The resin as a base resin can be synthesized by, for example, subjecting monomers that afford structural units to a polymerization reaction in an appropriate solvent using a publicly known radical polymerization initiator or the like.

The molecular weight of the resin as a base resin is not particularly limited, and the weight average molecular weight (Mw) in terms of polystyrene as determined by Gel Permeation Chromatography (GPC) is preferably 1,000 or more, more preferably 2,000 or more, still more preferably 3,000 or more, particularly preferably 4,000 or more. In addition, the Mw is preferably 50,000 or less, more preferably 30,000 or less, still more preferably 15,000 or less, particularly preferably 12,000 or less. When the Mw of the resin is within the above range, a resulting resist film is good in heat resistance and developability.

The ratio (Mw/Mn) of Mw to the number average molecular weight (Mn) of the resin as a base resin in terms of polystyrene as determined by GPC is usually 1 or more and 5 or less, preferably 1 or more and 3 or less, more preferably 1 or more and 2 or less.

The Mw and the Mn of the resin in the present description are values measured using Gel Permeation Chromatography (GPC) under the following conditions.
GPC column: G2000HXL×2, G3000HXL×1, G4000HXL×1 (all manufactured by Tosoh Corporation)
Column temperature: 40° C.
Elution solvent: tetrahydrofuran
Flow rate: 1.0 mL/min
Sample concentration: 1.0% by mass
Amount of sample injected: 100 μL
Detector: differential refractometer
Standard substance: monodisperse polystyrene

The content of the resin is preferably 70% by mass or more, more preferably 75% by mass or more, still more preferably 80% by mass or more based on the total solid content of the radiation sensitive resin composition.

### <Other Resins>

The radiation sensitive resin composition of the present embodiment may contain as another resin a resin having a higher mass content of fluorine atoms than that in the base resin as described above (hereinafter also referred as “high fluorine-containing resin”). When the radiation sensitive resin composition contains the high fluorine-containing resin, the high fluorine-containing resin can be localized in the surface layer of a resist film compared to the base resin, and as a result, the state of the surface of the resist film and the component distribution in the resist film can be controlled to a desired state.

The high fluorine-containing resin preferably has, for example, any one or more of the structural unit A to the structural unit E in the base resin, as necessary, and has a structural unit represented by the following formula (f0) (hereinafter, also referred to as “structural unit F”).

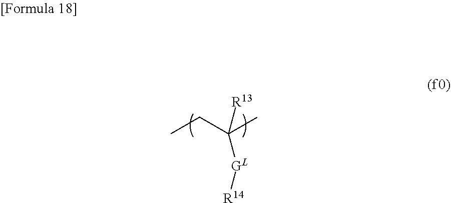

In the formula (f0), R¹³ is a hydrogen atom, a methyl group, or a trifluoromethyl group. G^{L} is a single bond, an oxygen atom, a sulfur atom, —COO—, —SO₂ONH—, —CONH—, or —OCONH—. R¹⁴ is a monovalent fluorinated chain hydrocarbon group having 1 to 20 carbon atoms or a monovalent fluorinated alicyclic hydrocarbon group having 3 to 20 carbon atoms.

As the R¹³, a hydrogen atom and a methyl group are preferable, and a methyl group is more preferable, from the viewpoint of the copolymerizability of a monomer that affords the structural unit F.

As the G^{L}, a single bond and —COO— are preferable, and —COO— is more preferable, from the viewpoint of the copolymerizability of a monomer that affords the structural unit F.

Examples of the monovalent fluorinated chain hydrocarbon group having 1 to 20 carbon atoms represented by R¹⁴ may include monovalent fluorinated chain hydrocarbon groups in which some or all of the hydrogen atoms of a linear or branched chain alkyl group having 1 to 20 carbon atoms are substituted with fluorine atoms.

Examples of the monovalent fluorinated alicyclic hydrocarbon group having 3 to 20 carbon atoms represented by R¹⁴ may include monovalent fluorinated alicyclic hydrocarbon groups in which some or all of the hydrogen atoms of a mono- or polycyclic hydrocarbon group having 3 to 20 carbon atoms are substituted with fluorine atoms.

As the R¹⁴, fluorinated chain hydrocarbon groups are preferable, fluorinated alkyl groups are more preferable, and a 2,2,2-trifluoroethyl group, a 1,1,1,3,3,3-hexafluoropropyl group, a 5,5,5-trifluoro-1,1-diethylpentyl group, and a 1,1,1,2,2,3,3-heptafluoro-6-methylheptan-4-yl group are still more preferable.

When the high fluorine-containing resin has the structural unit F, the content of the structural unit F is preferably 20 mol % or more, more preferably 30 mol % or more, still more preferably 40 mol % or more based on all structural units constituting the high fluorine-containing resin. In addition, the content is preferably 100 mol % or less, more preferably 95 mol % or less, still more preferably 90 mol % or less. When the content of the structural unit F is adjusted to within the above range, the content by mass of fluorine atoms in the high fluorine-containing resin can more appropriately be adjusted and the localization in the surface layer of a resist film can be further promoted.

The high fluorine-containing resin may have another structural unit in addition to the structural unit F. Examples of such another structural unit include a structural unit G having an alcoholic hydroxy group and having a fluorinated hydrocarbon group bonded to a carbon atom to which the alcoholic hydroxy group is bonded; and a structural unit H containing at least one selected from the group consisting of an iodine atom and a bromine atom.

When the high fluorine-containing resin has the structural unit G, the content of the structural unit G is preferably 10 mol % or more, more preferably 15 mol % or more, still more preferably 20 mol % or more based on all structural units constituting the high fluorine-containing resin. The content is preferably 70 mol % or less, more preferably 60 mol % or less, still more preferably 50 mol % or less. When the high fluorine-containing resin has the structural unit H, the content of the structural unit H is preferably 1 mol % or more, more preferably 3 mol % or more, still more preferably 5 mol % or more based on all structural units constituting the high fluorine-containing resin. The content is preferably 400 mol % or less, more preferably 30 mol % or less, still more preferably 20 mol % or less. When the contents of the structural unit G and the structural unit H are adjusted to within the above ranges, the surface of a resist film can be controlled to a desired state.

The Mw of the high fluorine-containing resin is preferably 1,000 or more, more preferably 2,000 or more, still more preferably 3,000 or more, particularly preferably 5,000 or more. The Mw is preferably 50,000 or less, more preferably 30,000 or less, still more preferably 20,000 or less, particularly preferably 15,000 or less.

The Mw/Mn of the high fluorine-containing resin is usually 1 or more, more preferably 1.1 or more. The Mw/Mn is usually 5 or less, preferably 3 or less, more preferably 2.5 or less, still more preferably 2.2 or less.

The content of the high fluorine-containing resin is preferably 1 part by mass or more, more preferably 2 parts by mass or more, still more preferably 3 parts by mass or more based on 100 parts by mass of the base resin (when the radiation sensitive acid generating resin and the resin are contained, the total amount thereof is taken). The content is preferably 20 parts by mass or less, more preferably 15 parts by mass or less, still more preferably 10 parts by mass or less. When the content of the high fluorine-containing resin is adjusted to within the above range, the high fluorine-containing resin can be more effectively localized in the surface layer of a resist film, and as a result, the elusion of a top portion of the pattern is suppressed during development and the rectangularity of the pattern can be enhanced. The radiation sensitive resin composition may contain one type or two or more types of high fluorine-containing resins.

### (Method for Synthesizing High Fluorine-Containing Resin)

The high fluorine-containing resin can be synthesized by the same method as the method for synthesizing the base resin described above.

### <Onium Salt>

The onium salt is a component that contains an organic acid anion moiety and an onium cation moiety and generates an acid through exposure to light. When the onium salt contains at least one group selected from the group consisting of a pentafluorosulfanyl group, a pentafluorosulfanyloxy group, and a pentafluorosulfanylthio group, it is possible to achieve high sensitivity due to improvement in acid generation efficiency and exhibition of LWR performance due to acid diffusion controllability.

While the form of the onium salt contained in the radiation sensitive resin composition is not particularly limited, the onium salt is preferably at least one type selected from the group consisting of a resin containing the structural unit B having the organic acid anion moiety and the onium cation moiety, a radiation sensitive acid generator containing the organic acid anion moiety and the onium cation moiety, and an acid diffusion control agent containing the organic acid anion moiety and the onium cation moiety and generating an acid having a higher pKa than that of an acid generated from the radiation sensitive acid generator through irradiation with radiation. These respective functions will be described below.

An acid generated through exposure of the onium salt to light is considered to be responsible for two functions in the radiation sensitive resin composition depending on the strength of the acid. The first function includes a function that causes the acid generated through exposure to light to dissociate an acid-dissociable group of a structural unit when the resin contains the structural unit having the acid-dissociable group, to generate a carboxy group or the like. An onium salt having the first function is referred to as a radiation sensitive acid generator. The second function includes a function that suppresses, by salt exchange, the diffusion of the acid generated from the radiation sensitive acid generator in the unexposed area without substantially dissociating the acid-dissociable group of the resin under a pattern formation condition in which the radiation sensitive resin composition is used. An onium salt having the second function is referred to as an acid diffusion control agent. The acid generated from the acid diffusion control agent can be said to be an acid relatively weaker (acid having a higher pKa) than the acid generated from the radiation sensitive acid generator. Whether the onium salt functions as the radiation sensitive acid generator or the acid diffusion control agent depends on the energy required for dissociating the acid-dissociable group of the resin and the acidity of the onium salt. The form of the radiation sensitive acid generator contained in the radiation sensitive resin composition may be a form in which the onium salt structure is present alone as a compound (released from a polymer), a form in which the onium salt structure is incorporated as a part of a polymer, or both of these forms. The form in which the onium salt structure is incorporated as a part of a polymer is particularly referred to as a radiation sensitive acid generating resin.

When the radiation sensitive resin composition contains the radiation sensitive acid generator or the radiation sensitive acid generating resin, the polarity of the resin on an exposed area increases, and as a result, when the developer is an aqueous alkaline solution, the resin on the exposed area is soluble in the developer, and on the other hand, when the developer is an organic solvent, the resin on the exposed area is hardly soluble in the developer.

When the radiation sensitive resin composition contains the acid diffusion control agent, diffusion of an acid on an unexposed area can be suppressed, and a resist pattern further superior in pattern developability and LWR performance can be formed.

In the radiation sensitive resin composition, it is preferable that the onium cation moiety in at least one type selected from the group consisting of the radiation sensitive acid generating resin, the radiation sensitive acid generator, and the acid diffusion control agent contain the aromatic ring structure having a fluorine atom.

Even in any contained form of the onium salt, the organic acid anion moiety preferably has at least one type selected from the group consisting of a sulfonate anion, a carboxylate anion, and a sulfonimide anion. The onium cation moiety is preferably at least one type selected from the group consisting of a sulfonium cation and an iodonium cation. When the onium salt has a combination of these structures, the functions can be efficiently exhibited.

Examples of the acid generated through exposure to light may include acids that generate sulfonic acid, carboxylic acid, and sulfonimide through exposure to light corresponding to the organic acid anion.

Examples of the onium salt that affords a sulfonic acid through exposure to light may include:
(1) a compound in which one or more fluorine atoms or fluorinated hydrocarbon groups are bonded to a carbon atom adjacent to a sulfonate anion, and
(2) a compound in which neither fluorine atom nor fluorinated hydrocarbon group is bonded to a carbon atom adjacent to a sulfonate anion.

Examples of the onium salt that affords a carboxylic acid through exposure to light may include:
(3) a compound in which one or more fluorine atoms or fluorinated hydrocarbon groups are bonded to a carbon atom adjacent to a carboxylate anion,
(4) a compound in which neither fluorine atom nor fluorinated hydrocarbon group is bonded to a carbon atom adjacent to a carboxylate anion.

Among them, as the radiation sensitive acid generator or the radiation sensitive acid generating resin, those corresponding to the above (1) are preferable. As the acid diffusion control agent, those corresponding to the above (2), (3), or (4) are preferable, and those corresponding to the above (2) or (4) are particularly preferable.

### <Radiation Sensitive Acid Generator>

The radiation sensitive resin composition preferably further includes the radiation sensitive acid generator that generates an acid having a lower pKa than that of the acid generated from the acid diffusion control agent through irradiation with radiation (exposure to light). When the radiation sensitive resin composition contains the radiation sensitive acid generator, the acid generated through exposure to light dissociates the acid-dissociable group of the resin to generate a carboxy group or the like. As a result, the polarity of the resin on the exposed area increases, so that in the case of development with an aqueous alkaline solution, the resin on the exposed area is soluble in the developer, whereas in the case of development with an organic solvent, the resin in the exposed area is hardly soluble in the developer.

The radiation sensitive acid generator contains the organic acid anion moiety and the onium cation moiety. The organic acid anion moiety preferably has at least one type selected from the group consisting of a sulfonate anion and a sulfonimide anion. Examples of the acid generated through exposure to light include a sulfonic acid and a sulfonimide corresponding to the organic acid anion moiety. The organic acid anion moiety preferably contains an iodine-substituted aromatic ring structure.

Among them, a compound in which one or more fluorine atoms or fluorinated hydrocarbon groups are bonded to a carbon atom adjacent to a sulfonate anion can be suitably employed as the radiation sensitive acid generator that affords a sulfonic acid through exposure to light.

The radiation sensitive acid generator is preferably represented by the following formula (A-1) or (A-2).

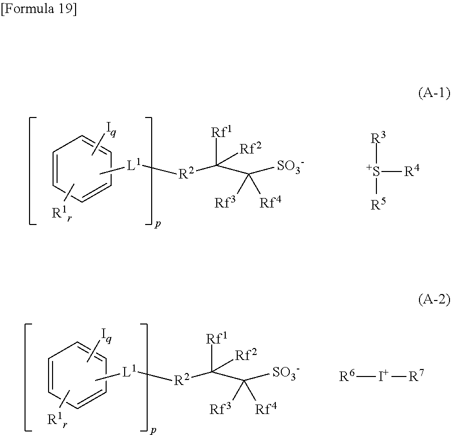

In the formulas (A-1) and (A-2), L¹ is a single bond, an ether linkage, an ester linkage, or an alkylene group having 1 to 6 carbon atoms optionally containing an ether linkage or an ester linkage. The alkylene group may be linear, branched, or cyclic.

R¹ is a hydroxy group, a carboxy group, a fluorine atom, a chlorine atom, a bromine atom, a pentafluorosulfanyl group, a pentafluorosulfanyloxy group, a pentafluorosulfanylthio group, or an amino group, or an alkyl group having 1-20 carbon atoms, an alkoxy group having 1-20 carbon atoms, an alkoxycarbonyl group having 2-10 carbon atoms, an acyloxy group having 2-20 carbon atoms, or an alkylsulfonyloxy group having 1-20 carbon atoms optionally containing a fluorine atom, a chlorine atom, a bromine atom, a hydroxy group, an amino group, or an alkoxy group having 1-10 carbon atoms, or —NR⁸—C(═O)—R⁹ or —NR⁸—C(═O)—O—R⁹. R⁸ is a hydrogen atom or an alkyl group having 1 to 6 carbon atoms optionally containing a halogen atom, a hydroxy group, an alkoxy group having 1 to 6 carbon atoms, an acyl group having 2 to 6 carbon atoms or an acyloxy group having 2 to 6 carbon atoms. R⁹ is an alkyl group having 1 to 16 carbon atoms, an alkenyl group having 2 to 16 carbon atoms, or an aryl group having 6 to 12 carbon atoms, optionally containing a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among them, R¹ is preferably a hydroxy group, —NR⁸—C(═O)—R⁹, a fluorine atom, a chlorine atom, a bromine atom, a pentafluorosulfanyl group, a pentafluorosulfanyloxy group, a pentafluorosulfanylthio group, a methyl group, a methoxy group, or the like.

R² is a single bond or a divalent linking group having 1 to 20 carbon atoms when p is 1, and is a trivalent or tetravalent linking group having 1 to 20 carbon atoms when p is 2 or 3, which linking groups may contain an oxygen atom, a sulfur atom, or a nitrogen atom.

Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may be combined to form a carbonyl group. In particular, both Rf³ and Rf⁴ are preferably fluorine atoms.

R³, R⁴, R⁵, R⁶, and R⁷ are each independently a monovalent hydrocarbon group having 1 to 20 carbon atoms optionally containing a hetero atom. Any two of R³, R⁴, and R⁵ may be bonded to each other to form a ring together with a sulfur atom to which two thereof are bonded. The monovalent hydrocarbon group may be linear, branched, or cyclic, and specific examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be substituted with a hydroxy group, a carboxy group, a halogen atom, a pentafluorosulfanyl group, a pentafluorosulfanyloxy group, a pentafluorosulfanylthio group, a cyano group, an amide group, a nitro group, a mercapto group, a sultone group, a sulfone group, or a sulfonium salt-containing group, and some of the carbon atoms of these groups may be substituted with an ether linkage, an ester linkage, a carbonyl group, a carbonate group, or a sulfonate ester linkage.

p is an integer satisfying 1≤p≤3. q and r are integers satisfying 0≤q≤5, 0≤r≤3, and 0≤q+r≤5. q is preferably an integer satisfying 1≤q≤3, more preferably 2 or 3. r is preferably an integer satisfying 0≤r≤2. When r is an integer satisfying 1≤r≤3, at least one R¹ is preferably a fluorine atom, a fluorinated hydrocarbon group, a pentafluorosulfanyl group, a pentafluorosulfanyloxy group, or a pentafluorosulfanylthio group, and at least one R¹ is more preferably a pentafluorosulfanyl group, a pentafluorosulfanyloxy group, or a pentafluorosulfanylthio group.

Examples of the organic acid anion moiety of the radiation sensitive acid generators represented by the formulas (A-1) and (A-2) include, but are not limited to, those shown below. As organic acid anion moieties having no iodine-substituted aromatic ring structure, a structure in which the iodine atoms in the formulas shown below are substituted with an atom or a group other than an iodine atom such as a hydrogen atom or another substituent can be suitably employed.

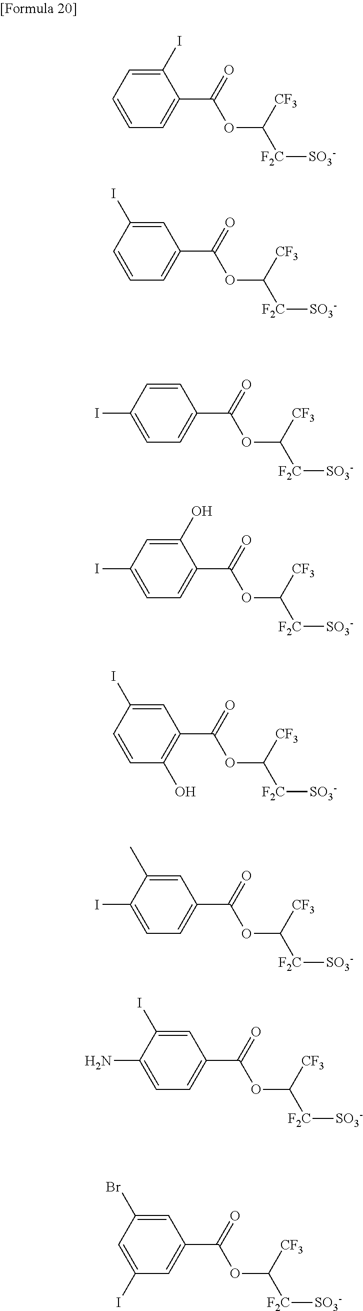

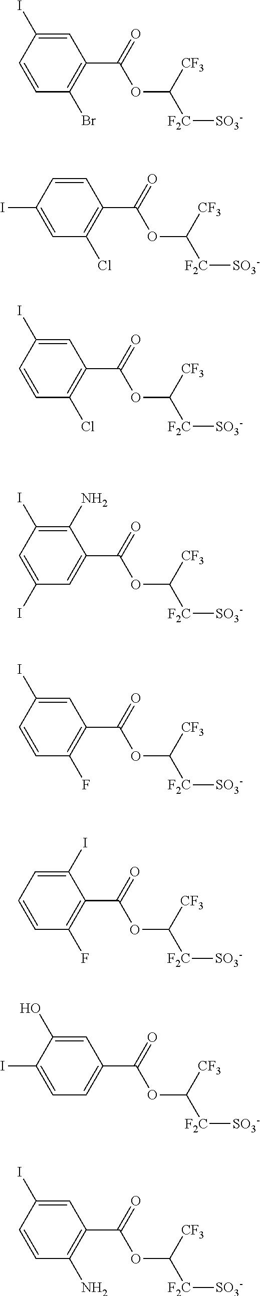

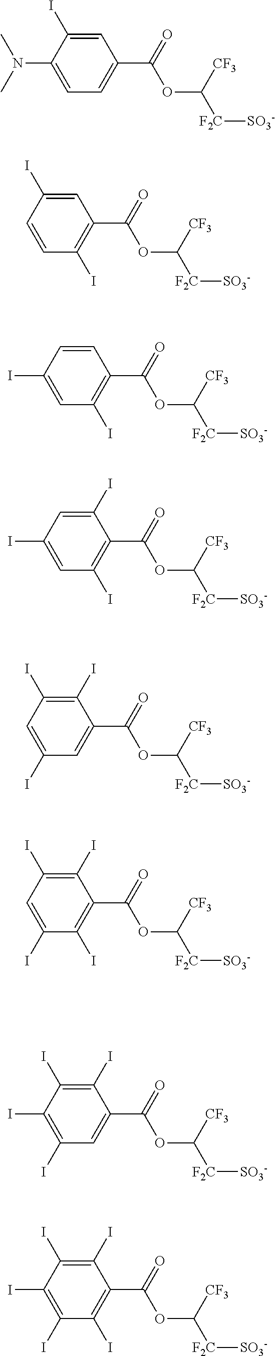

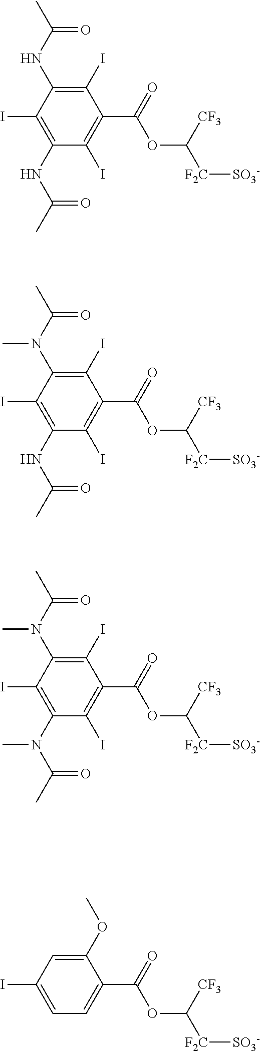

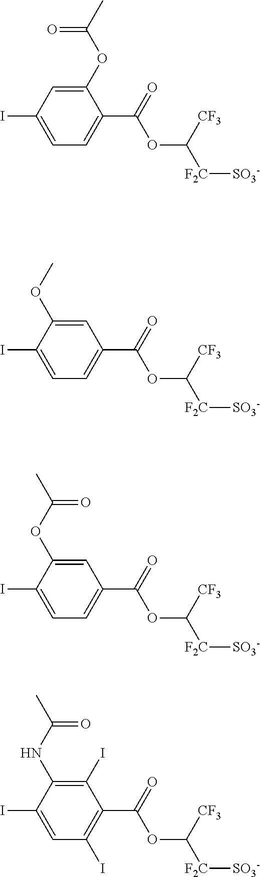

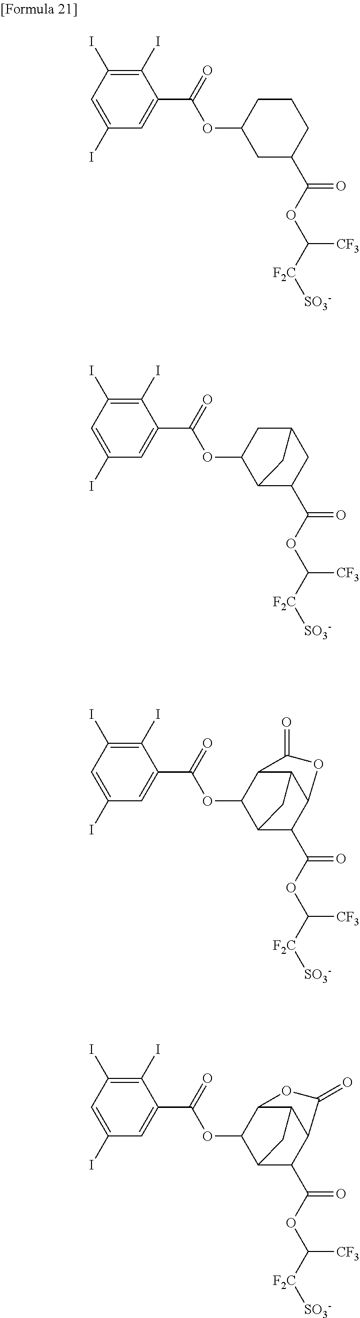

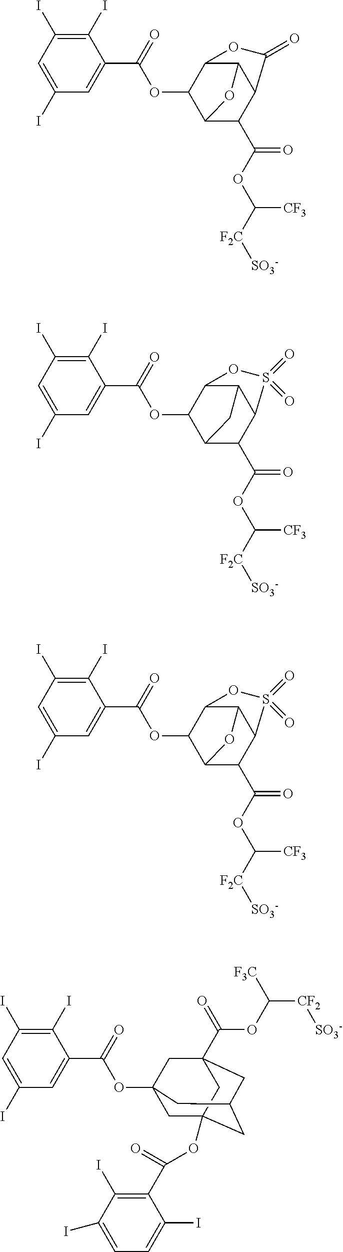

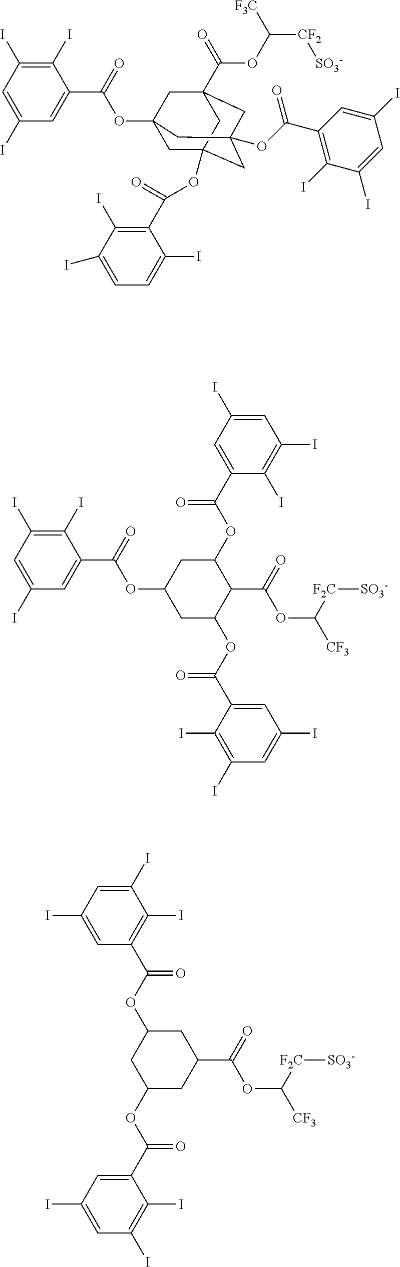

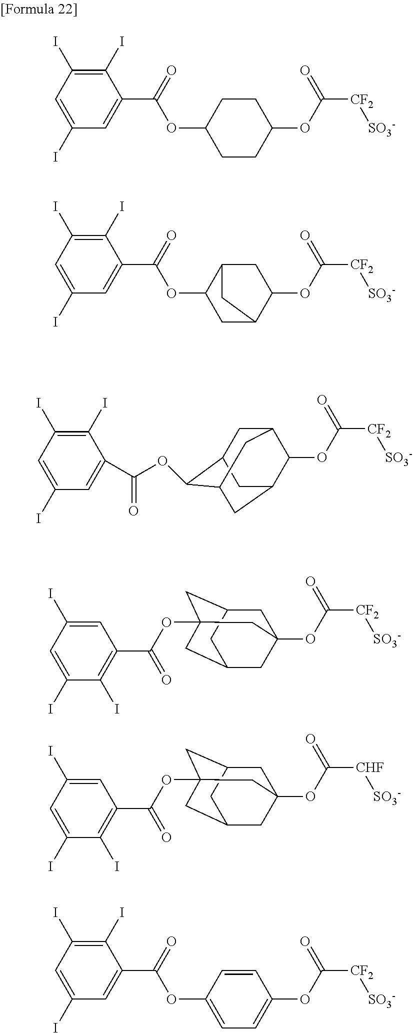

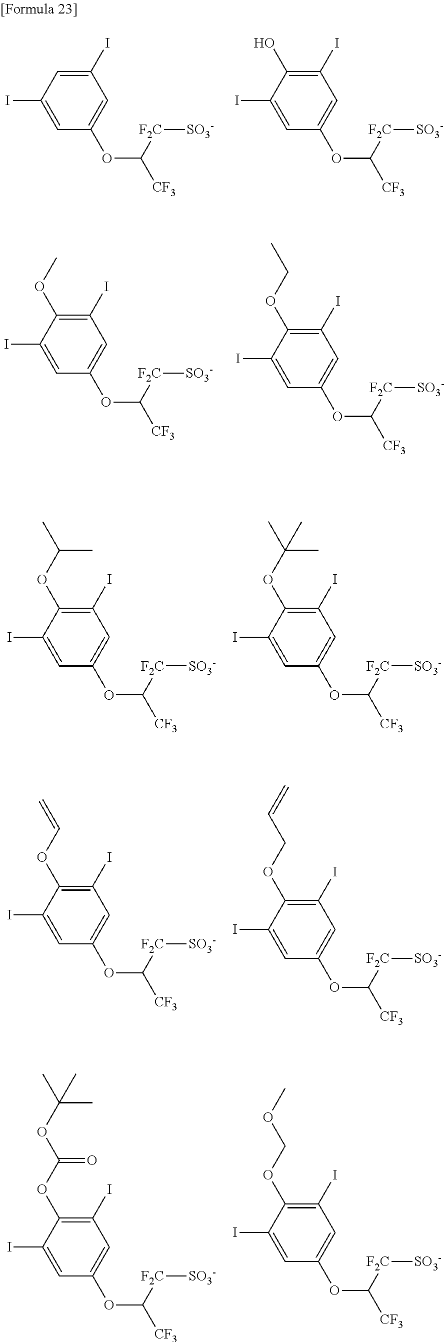

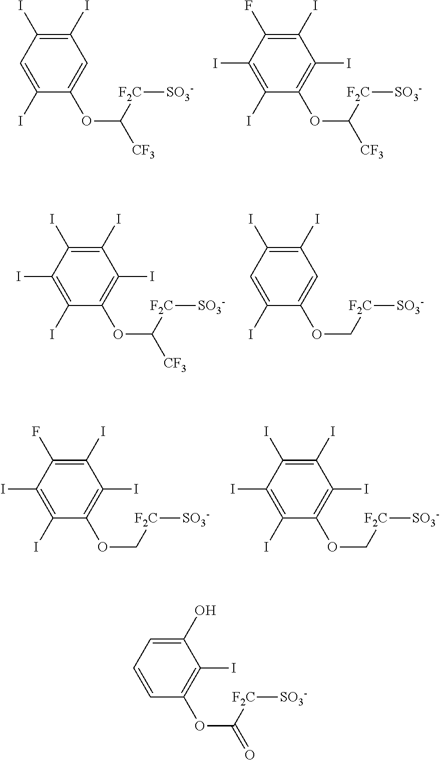

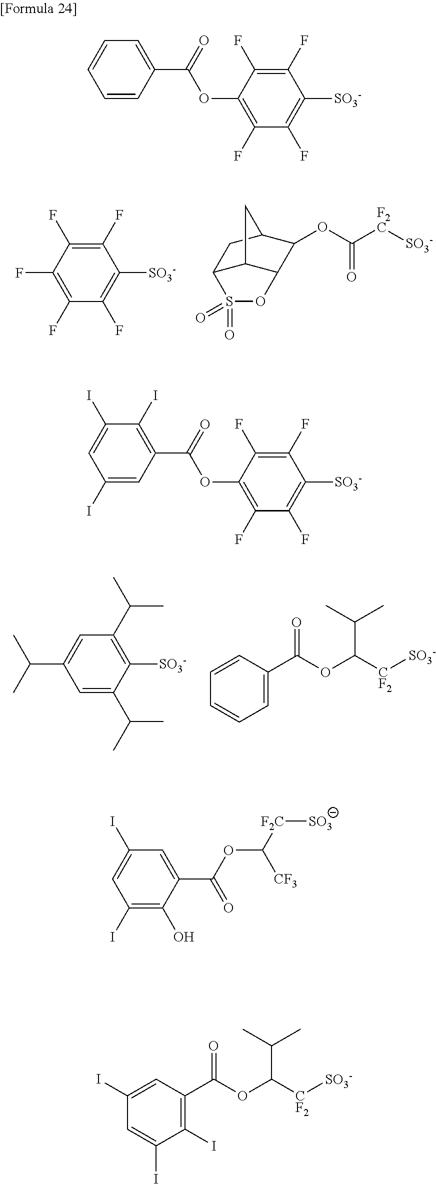

As the onium cation moiety in the radiation sensitive acid generator represented by the formula (A-1), the structures disclosed as the onium cation moiety in the structural unit B that can be contained in the resin can be suitably employed. Among them, an onium cation containing an aromatic ring structure having a fluorine atom is preferable, and an onium cation containing an aromatic ring structure having a fluorine atom, a CF₃ group, a pentafluorosulfanyl group, a pentafluorosulfanyloxy group, or a pentafluorosulfanylthio group is more preferable. Specific examples thereof may include an onium cation represented by the above formula (Q-1), and in this case, at least one or more Ra₃s in the formula (Q-1) are a pentafluorosulfanyl group, a pentafluorosulfanyloxy group, or a pentafluorosulfanylthio group.

These radiation sensitive acid generators may be used alone, or two or more thereof may be used in combination. The lower limit of the content of the radiation sensitive acid generator is preferably 0.5 parts by mass, more preferably 1 part by mass, still more preferably 1.5 parts by mass, particularly preferably 2 parts by mass per 100 parts by mass of the base resin. The upper limit of the content is preferably 20 parts by mass or less, more preferably 18 parts by mass or less, still more preferably 15 parts by mass or less, particularly preferably 12 parts by mass or less based on 100 parts by mass of the resin. This makes it possible to exhibit superior sensitivity or LWR performance when forming a resist pattern.

In combination with the radiation sensitive acid generator containing at least one group selected from the group consisting of a pentafluorosulfanyl group, a pentafluorosulfanyloxy group, and a pentafluorosulfanylthio group, a radiation sensitive acid generator containing none of a pentafluorosulfanyl group, a pentafluorosulfanyloxy group, and a pentafluorosulfanylthio group (hereinafter, also referred to as “another radiation sensitive acid generator”) may be used. When another radiation sensitive acid generator is contained, the upper limit of the content of the other radiation sensitive acid generator is preferably 45% by mass or less, more preferably 35% by mass or less, still more preferably 25% by mass or less based on the total content of the radiation sensitive acid generator. The lower limit of the content of the other radiation sensitive acid generator is 1% by mass or more based on the total content of the radiation sensitive acid generator.

### <Acid Diffusion Control Agent>

The acid diffusion control agent contains the organic acid anion moiety and the onium cation moiety, and generates an acid having a higher pKa than that of an acid generated from the radiation sensitive acid generator through irradiation with radiation. The organic acid anion moiety includes carboxylic acids. The organic acid anion moiety preferably contains an iodine-substituted aromatic ring structure. The acid diffusion control agent is preferably represented by the following formula (S-1) or (S-2).

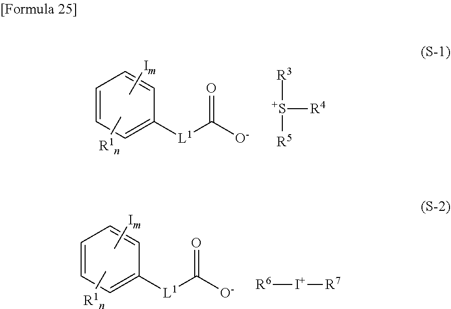

In the formulas (S-1) and (S-2), R¹ is a hydrogen atom, a hydroxy group, a fluorine atom, a chlorine atom, a bromine atom, a pentafluorosulfanyl group, a pentafluorosulfanyloxy group, a pentafluorosulfanylthio group, an amino group, a nitro group, or a cyano group, or an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms optionally substituted with a halogen atom, or —NR^{1A}—C(═O)—R^{1B} or —NR^{1A}—C(═O)—O—R^{1B}. R^{1A} is a hydrogen atom or an alkyl group having 1 to 6 carbon atoms, and R^{1B} is an alkyl group having 1 to 6 carbon atoms or an alkenyl group having 2 to 8 carbon atoms.

The alkyl group having 1 to 6 carbon atoms may be linear, branched, or cyclic, and specific examples thereof include a methyl group, an ethyl group, an n-propyl group, an isopropyl group, a cyclopropyl group, an n-butyl group, an isobutyl group, a sec-butyl group, a tert-butyl group, a cyclobutyl group, an n-pentyl group, a cyclopentyl group, an n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include those the same as the specific examples of the alkyl group described above, and examples of the alkyl moiety of the alkylsulfonyloxy group having 1 to 4 carbon atoms include those having 1 to 4 carbon atoms among the specific examples of the alkyl group described above. The alkenyl group having 2 to 8 carbon atoms may be linear, branched, or cyclic, and specific examples thereof include a vinyl group, a 1-propenyl group, and a 2-propenyl group. Among them, a fluorine atom, a chlorine atom, a pentafluorosulfanyl group, a hydroxy group, an amino group, an alkyl group having 1 to 3 carbon atoms, an alkoxy group having 1 to 3 carbon atoms, an acyloxy group having 2 to 4 carbon atoms, —NR^{1A}—C(═O)—R^{1B}, and —NR^{1A}—C(═O)—O—R^{1B} are preferable as R¹.

R³, R⁴, R⁵, R⁶, and R⁷ are each independently a monovalent hydrocarbon group having 1 to 20 carbon atoms optionally containing a hetero atom. When the onium cation moiety of the acid diffusion control agent has a fluorine atom, at least one of R³, R⁴, and R⁵ contains one or more fluorine atoms, and at least one of R⁶ and R⁷ contains one or more fluorine atoms. Any two of R³, R⁴, and R⁵ may be bonded to each other to form a ring together with a sulfur atom to which two thereof are bonded. The monovalent hydrocarbon group may be linear, branched, or cyclic, and specific examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be substituted with a hydroxy group, a carboxy group, a halogen atom, a cyano group, an amide group, a nitro group, a mercapto group, a sultone group, a sulfone group, or a sulfonium salt-containing group, and some of the carbon atoms of these groups may be substituted with an ether linkage, an ester linkage, a carbonyl group, a carbonate group, or a sulfonate ester linkage.

L¹ is a single bond or a divalent linking group having 1 to 20 carbon atoms, optionally containing an ether linkage, a carbonyl group, an ester linkage, an amide linkage, a sultone ring, a lactam ring, a carbonate linkage, a halogen atom, a hydroxy group, or a carboxy group.

m and n are integers satisfying 0≤m≤5, 0≤n≤3, and 0≤m+n≤5, and preferably integers satisfying 1≤m≤3 and 0≤n≤2. When n is an integer satisfying 1≤n≤3, at least one R¹ is preferably a fluorine atom, a fluorinated hydrocarbon group, a pentafluorosulfanyl group, a pentafluorosulfanyloxy group, or a pentafluorosulfanylthio group, and at least one R¹ is more preferably a pentafluorosulfanyl group, a pentafluorosulfanyloxy group, or a pentafluorosulfanylthio group.

Examples of the organic acid anion moiety of the acid diffusion control agent represented by the formula (S-1) or (S-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are substituted with an atom or group other than an iodine atom such as a hydrogen atom or another substituent.

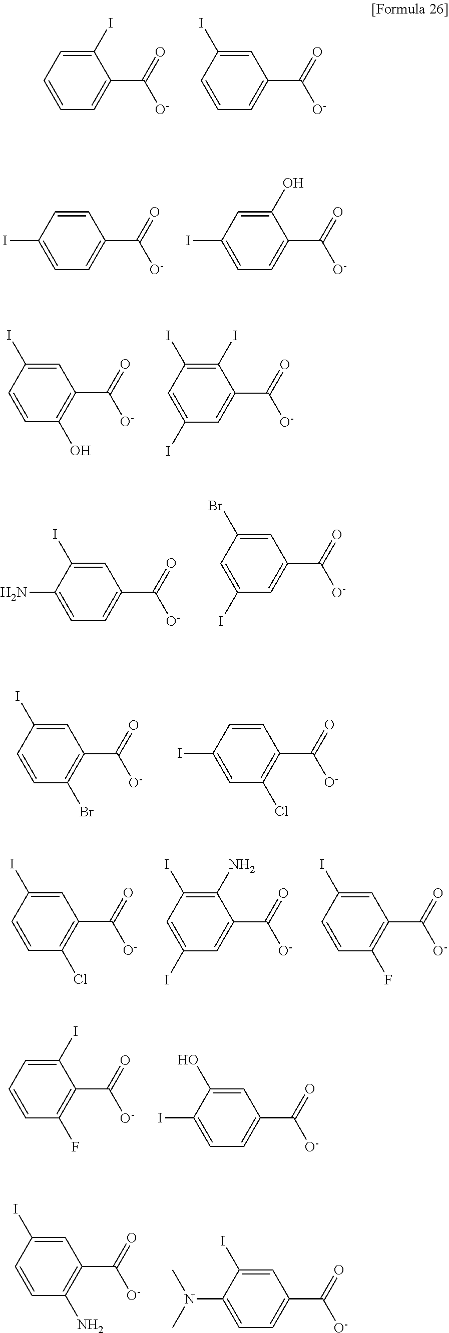

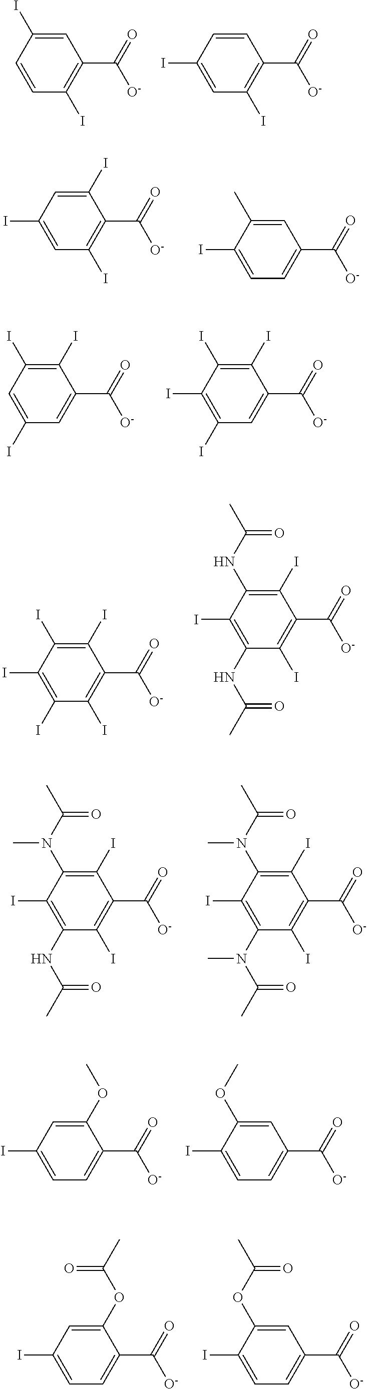

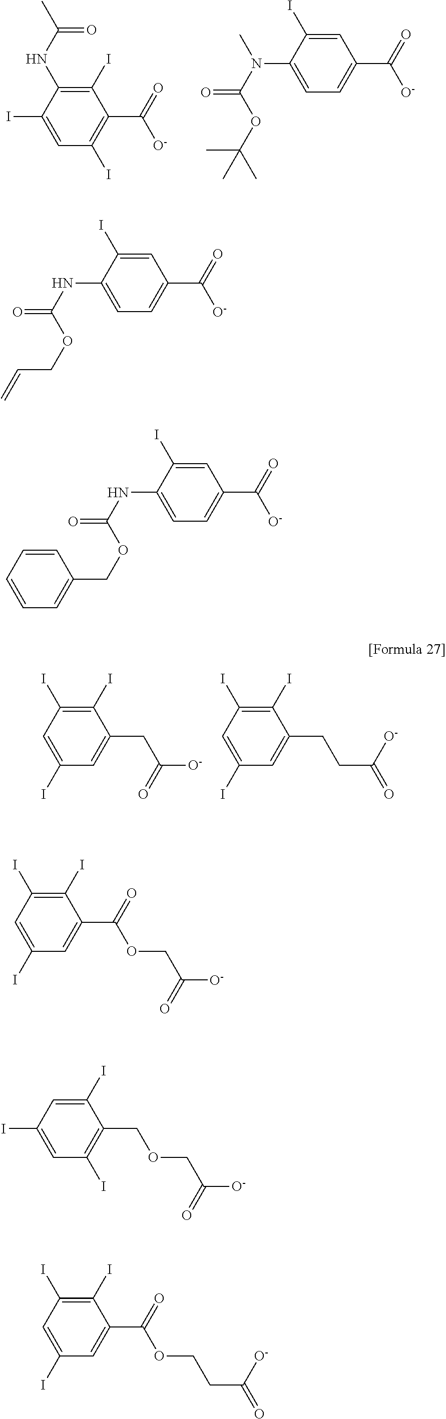

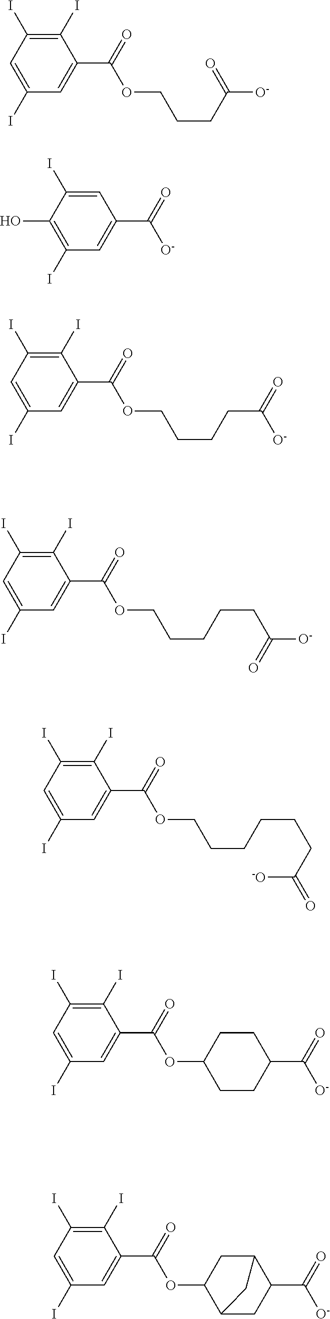

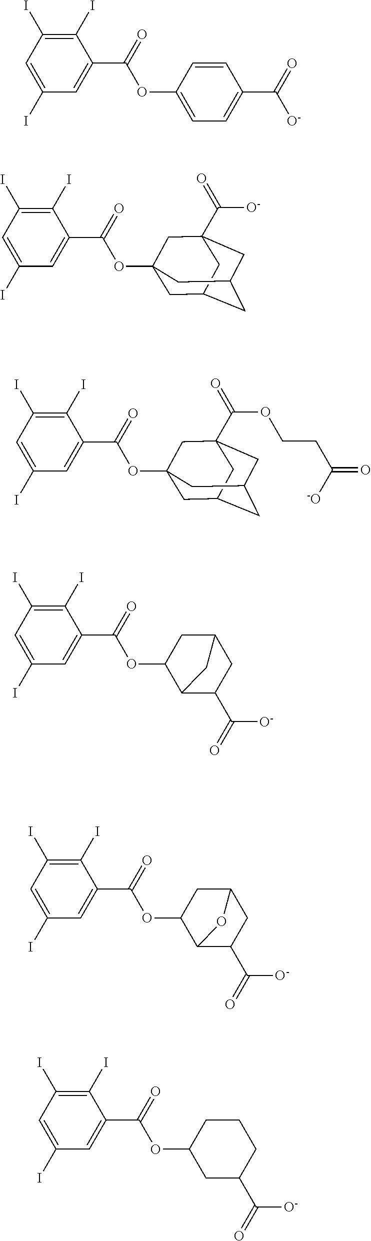

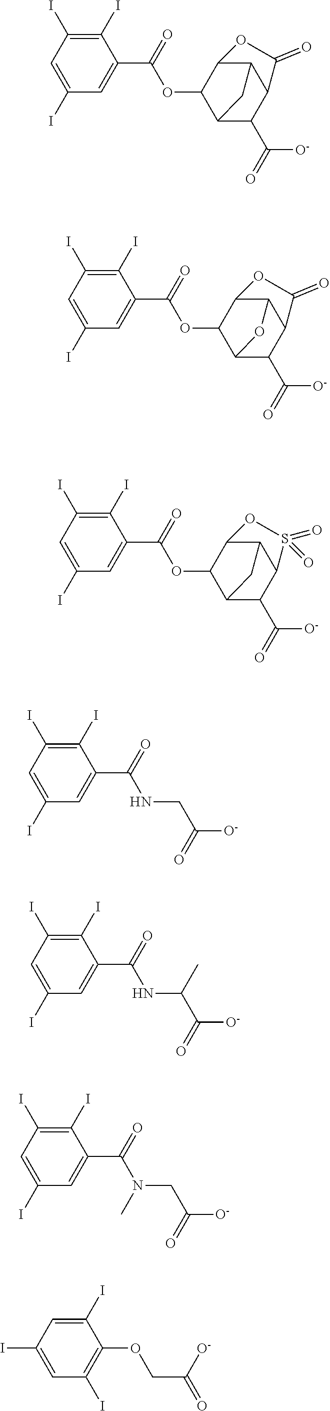

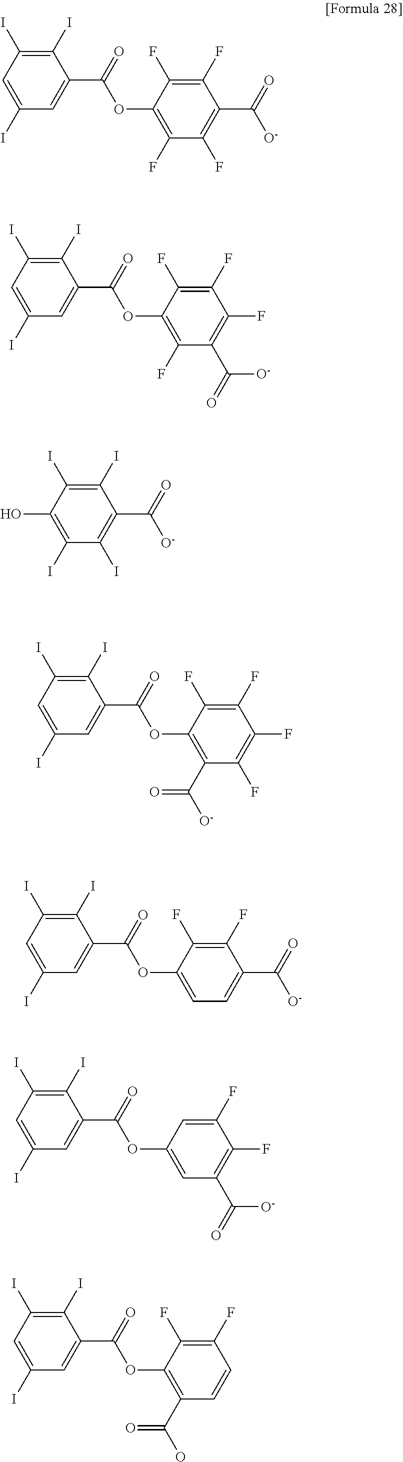

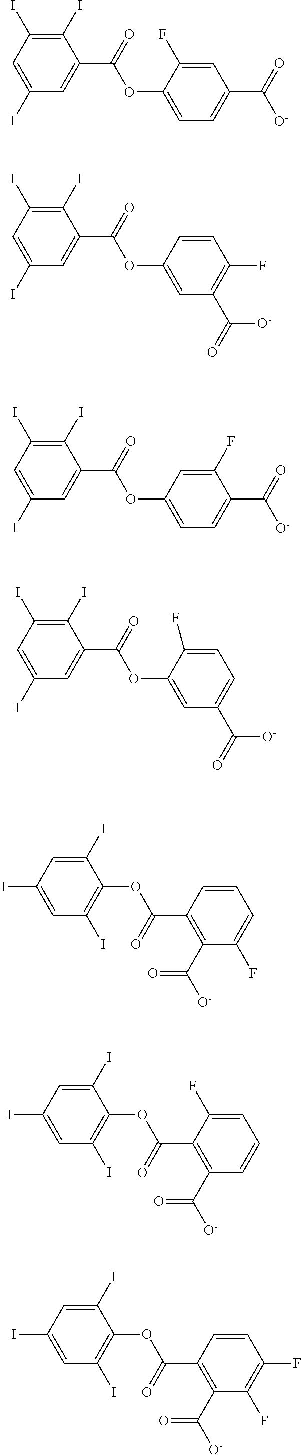

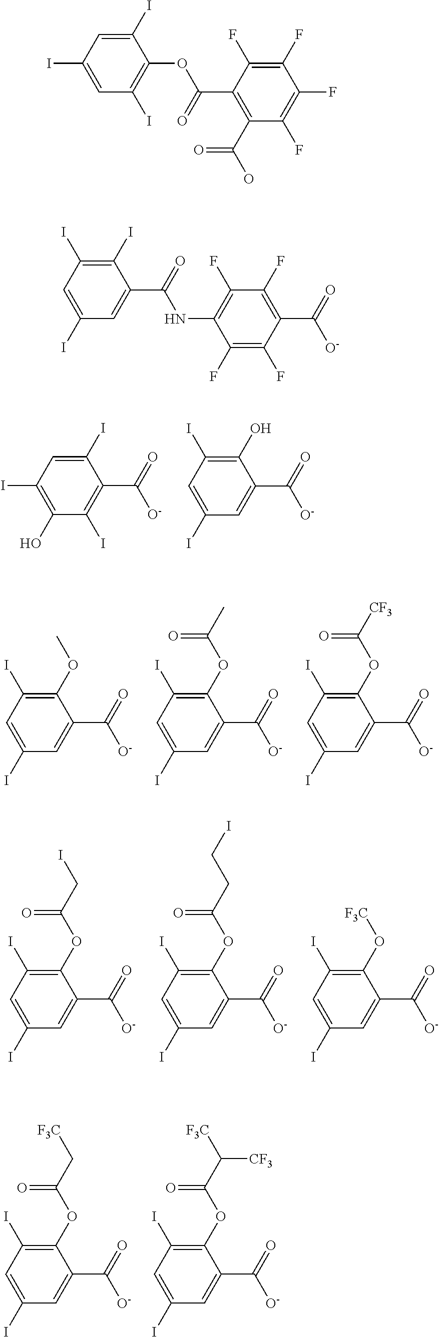

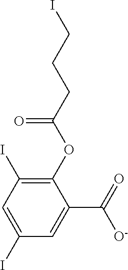 [SMILES: O=C(CCCI)Oc1c(I)cc(I)cc1C(=O)[O-]]

As the onium cation moieties in the acid diffusion control agents represented by the formulas (S-1) and (S-2), the onium cation moiety in the structural unit B of the radiation sensitive acid generating resin can be suitably employed. Among them, an onium cation containing an aromatic ring structure having a fluorine atom is preferable, and an onium cation containing an aromatic ring structure having a fluorine atom, a CF₃ group, a pentafluorosulfanyl group, a pentafluorosulfanyloxy group, or a pentafluorosulfanylthio group is more preferable. Specific examples thereof may include an onium cation represented by the formula (Q-1), and in this case, at least one or more Ra₃s in the formula (Q-1) are a pentafluorosulfanyl group, a pentafluorosulfanyloxy group, or a pentafluorosulfanylthio group.

The acid diffusion control agents represented by the formulas (S-1) and (S-2) can also be synthesized by a known method, particularly by a salt exchange reaction. A known acid diffusion control agent may also be used as long as the effect of the present invention is not impaired.

These acid diffusion control agents may be used alone, or two or more thereof may be used in combination. The content of the acid diffusion control agent is preferably 10% by mass or more, more preferably 15% by mass or more, still more preferably 20% by mass or more based on the content of the radiation sensitive acid generator (when a radiation sensitive acid generating resin is contained, the total amount with the content of the structural unit B in 100 parts by mass of the radiation sensitive acid generating resin is taken). The content is preferably 100% by mass or less, more preferably 80% by mass or less, still more preferably 60% by mass or less. This makes it possible to exhibit superior sensitivity or LWR performance when forming a resist pattern.

### <Solvent>

The radiation sensitive resin composition according to the present embodiment contains a solvent. The solvent is not particularly limited as long as it is a solvent capable of dissolving or dispersing at least the base resin (at least one of the radiation sensitive acid generating resin and the resin) and an additive or the like which is contained as desired.

Examples of the solvent include alcohol-based solvents, ether-based solvents, ketone-based solvents, amide-based solvents, ester-based solvents, and hydrocarbon-based solvents.

Examples of the alcohol-based solvents include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents in which some of the hydroxy groups of the polyhydric alcohol-based solvent are etherized.

Examples of the ether-based solvents include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents in which the hydroxy groups of the polyhydric alcohol-based solvent are etherized.

Examples of the ketone-based solvents include:
chain ketone-based solvents, such as acetone, butanone, and methyl-iso-butyl ketone;
cyclic ketone-based solvents, such as cyclopentanone, cyclohexanone, and methylcyclohexanone; and
2,4-pentanedione, acetonylacetone, and acetophenone.

Examples of the amide-based solvents include:
cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvents include:
monocarboxylate ester-based solvents, such as n-butyl acetate and ethyl lactate;
polyhydric alcohol portion ether acetate-based solvents, such as diethylene glycol mono-n-butyl ether acetate, propylene glycol monomethyl ether acetate, and dipropylene glycol monomethyl ether acetate;
lactone-based solvents, such as γ-butyrolactone and valerolactone;
carbonate-based solvents, such as diethyl carbonate, ethylene carbonate, and propylene carbonate; and
polyvalent carboxylate diester-based solvents, such as propylene glycol diacetate, methoxytriglycol acetate, diethyl oxalate, ethyl acetoacetate, ethyl lactate, and diethyl phthalate.

Examples of the hydrocarbon-based solvents include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, ester-based solvents and ketone-based solvents are preferable, polyhydric alcohol portion ether acetate-based solvents, cyclic ketone-based solvents, and lactone-based solvents are more preferable, and propylene glycol monomethyl ether acetate, cyclohexanone, and γ-butyrolactone are still more preferable. The radiation sensitive resin composition may contain one type or two or more types of solvent.

### <Other Optional Components>

The radiation sensitive resin composition may contain another optional component in addition to the components described above. Examples of the other optional component may include a crosslinking agent, a localization enhancing agent, a surfactant, an alicyclic backbone-containing compound, and a sensitizer. Such other optional components may be used singly, or two or more types thereof may be used in combination.

### <Method for Preparing Radiation Sensitive Resin Composition>

The radiation sensitive resin composition can be prepared, for example, by mixing the base resin, the onium salt, and the solvent, and if necessary, the other optional component at a prescribed ratio. The radiation sensitive resin composition is preferably filtered through, for example, a filter having a pore size of about 0.05 μm after mixing. The solid content concentration of the radiation sensitive resin composition is usually 0.1% by mass to 50% by mass, preferably 0.5% by mass to 30% by mass, more preferably 1% by mass to 20% by mass.

### <Compound>

The compound according to the present embodiment contains the onium salt containing the organic acid anion moiety and the onium cation moiety, in which the onium salt contains at least one group selected from the group consisting of a pentafluorosulfanyl group, a pentafluorosulfanyloxy group, and a pentafluorosulfanylthio group. In the present embodiment, the organic acid anion moiety may contain at least one group selected from the group consisting of a pentafluorosulfanyl group, a pentafluorosulfanyloxy group, and a pentafluorosulfanylthio group. In this case, the organic acid anion preferably has at least one selected from the group consisting of a sulfonate anion, a carboxylate anion, and a sulfonimide anion. In the present embodiment, the onium cation moiety may contain at least one group selected from the group consisting of a pentafluorosulfanyl group, a pentafluorosulfanyloxy group, and a pentafluorosulfanylthio group. Alternatively, both the organic acid anion moiety and the onium cation moiety may contain at least one group selected from the group consisting of a pentafluorosulfanyl group, a pentafluorosulfanyloxy group, and a pentafluorosulfanylthio group. Since the compound according to the present embodiment has a high level of sensitivity, it can impart LWR performance and a process window at a high level when used as a radiation sensitive acid generator or an acid diffusion control agent in a radiation sensitive resin composition.

### <Pattern Forming Method>

A method for forming a pattern in the present invention includes:
step (1) of applying the radiation sensitive resin composition directly or indirectly to a substrate to form a resist film (hereinafter, also referred to as “resist film forming step”);
step (2) of exposing the resist film to light (hereinafter, also referred to as “exposure step”); and
step (3) of developing the exposed resist film (hereinafter, also referred to as “development step”).

In accordance with this pattern forming method, a high-quality resist pattern can be formed because of the use of the radiation sensitive resin composition superior in sensitivity and LWR performance in the exposure step. Hereinafter, each of the steps will be described.

### [Resist Film Forming Step]

In this step (the step (1)), a resist film is formed of the radiation sensitive resin composition. Examples of the substrate on which the resist film is formed may include conventionally known substrates such as a silicon wafer, silicon dioxide, and a wafer coated with aluminum. An organic or inorganic antireflective film disclosed in, for example, JP-B-6-12452 or JP-A-59-93448 may be formed on the substrate. Examples of an applying method may include spin coating, cast coating, and roll coating. After the application, prebaking (PB) may be performed to volatilize the solvent in the coating film, if necessary. The PB temperature is usually 60° C. to 140° C., preferably 80° C. to 120° C. The PB time is usually 5 seconds to 600 seconds, preferably 10 seconds to 300 seconds. The thickness of the formed resist film is preferably 10 nm to 1,000 nm, more preferably 10 nm to 500 nm.

In the case of performing immersion exposure, regardless of the presence or absence of a water repellent polymer additive such as the high fluorine-containing resin in the radiation sensitive resin composition, a protective film for immersion insoluble in an immersion liquid may be provided on the formed resist film for the purpose of avoiding direct contact between the immersion liquid and the resist film. As the protective film for immersion, either a solvent-removable protective film that is to be removed by a solvent before the development step (see, for example, JP-A-2006-227632) or a developer-removable protective film that is to be removed simultaneously with the development in the development step (see, for example, WO 2005/069076 A1 and WO 2006/035790 A1) may be used. However, from the viewpoint of throughput, it is preferable to use a developer-removable protective film for immersion.

### [Exposure Step]

In this step (the step (2)), the resist film formed in the resist film forming step, namely the step (1), is irradiated with radiation for exposure through a photomask (in some cases, through an immersion medium such as water). Examples of the radiation used for exposure may include an electromagnetic wave including visible ray, ultraviolet ray, far ultraviolet ray, extreme ultraviolet ray (EUV), X ray, or γ ray; and a charged particle radiation such as an electron beam or a ray. Among them, far ultraviolet ray, electron beam, and EUV are preferable, ArF excimer laser light (wavelength: 193 nm), KrF excimer laser light (wavelength: 248 nm), electron beam, and EUV are more preferable, and an electron beam having a wavelength of 50 nm or less, which is positioned as next-generation exposure technology, and EUV are still more preferable.

When the exposure to light is performed by immersion exposure, examples of the immersion liquid to be used may include water and a fluorine-based inert liquid. The immersion liquid is preferably a liquid that is transparent to an exposure wavelength and has a temperature coefficient of refractive index as small as possible to minimize the distortion of an optical image projected onto the film. Particularly, when the exposure light source is ArF excimer laser light (wavelength: 193 nm), water is preferably used from the viewpoint of availability and easiness of handling in addition to the above-described viewpoints. When water is used, an additive that reduces the surface tension of water and increases the surface activity may be added in a small proportion. This additive is preferably one that does not dissolve the resist film on a wafer and has negligible influence on an optical coating at an under surface of a lens. The water to be used is preferably distilled water.

After the exposure, post exposure baking (PEB) is preferably performed to promote the dissociation of the acid-dissociable group of the resin or the like due to the acid generated from the radiation sensitive acid generator through exposure to light in the exposed area of the resist film. This PEB causes a difference in solubility in the developer between the exposed portion and the unexposed portion. The PEB temperature is usually 50° C. to 180° C., preferably 80° C. to 130° C. The PEB time is usually 5 seconds to 600 seconds, preferably 10 seconds to 300 seconds.

### [Development Step]

In this step (the step (3)), the resist film exposed in the exposure step, namely the step (2), is developed. This can form a predetermined resist pattern. After the development, the film is generally washed with a rinsing liquid such as water or alcohol, and then dried.

Examples of the developer used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

In the case of organic solvent development, examples of the solvent may include organic solvents such as hydrocarbon-based solvents, ether-based solvents, ester-based solvents, ketone-based solvents, and alcohol-based solvents, and solvents containing an organic solvent. Examples of the organic solvent may include one type or two or more types of solvent among the solvents listed as the solvent for the radiation sensitive resin composition. Among them, ester-based solvents and ketone-based solvents are preferable. As the ester-based solvents, acetate ester-based solvents are preferable, and n-butyl acetate and amyl acetate are more preferable. As the ketone-based solvents, chain ketones are preferable, and 2-heptanone is more preferable. The content of the organic solvent in the developer is preferably 80% by mass or more, more preferably 90% by mass or more, still more preferably 95% by mass or more, particularly preferably 99% by mass or more. Examples of a component other than the organic solvent in the developer may include water and silicon oil.

Examples of a developing method may include a method in which a substrate is immersed in a bath filled with a developer for a certain period of time (dipping method), a developing method in which a developer is allowed to be raised on a surface of a substrate due to surface tension and to stand for a certain period of time (puddle method), a method in which a developer is sprayed onto a surface of a substrate (spray method), and a method in which a developer is discharged onto a substrate that is rotated at a constant speed while a developer discharge nozzle is scanned at a constant speed (dynamic dispensing method).

### EXAMPLES

Hereinafter, the present invention will be specifically described with reference to Synthesis Examples, Examples, and Comparative Examples, but is not limited to the following Examples. The methods for measuring various physical property values are described below.

### [Mw and Mn]

The Mw and the Mn of polymers were measured by Gel Permeation Chromatography (GPC) using GPC columns manufactured by Tosoh Corporation (“G2000HXL”×2, “G3000HXL”×1, “G4000HXL”×1) under the following conditions.
Eluant: tetrahydrofuran (manufactured by Wako Pure Chemical Industries, Ltd.)
Flow rate: 1.0 mL/min
Sample concentration: 1.0% by mass
Amount of sample injected: 100 μL
Column temperature: 40° C.
Detector: differential refractometer
Standard substance: monodisperse polystyrene

### [A] Synthesis of Polymer

Monomers (hereinafter, also referred to as “compound (M-1) to compound (M-11)”) used in the synthesis of each polymer are shown below.

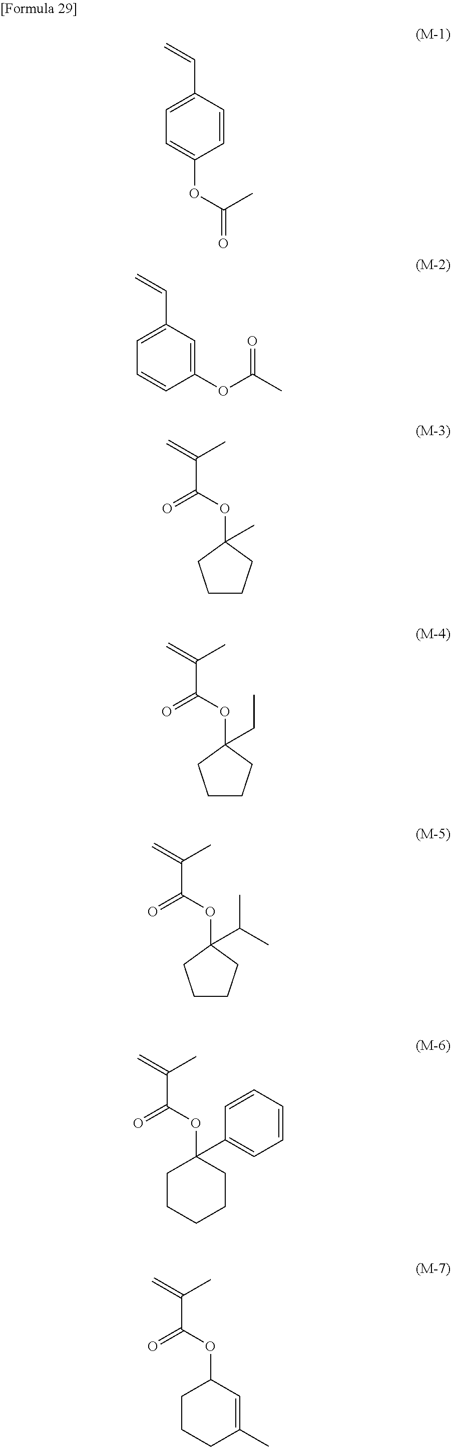

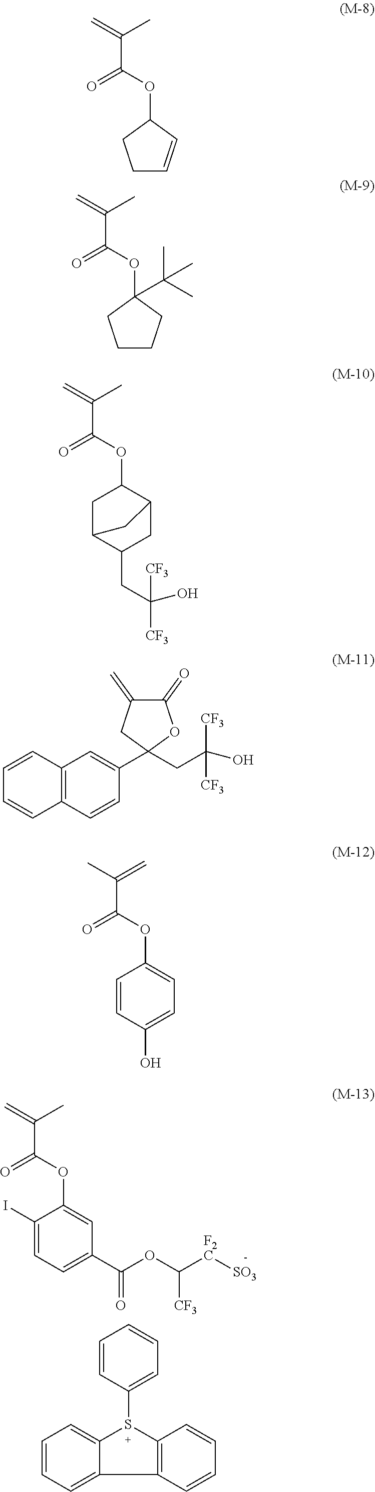

### [Polymer Synthesis Example 1] Synthesis of Polymer (A-1)

Compound (M-1) and compound (M-3) were dissolved in 1-methoxy-2-propanol (200 parts by mass based on the total amount of monomers) so as to have a molar ratio of 40/60. Next, azobisisobutyronitrile was added as an initiator in an amount of 6 mol % based on all the monomers to prepare a monomer solution. On the other hand, 1-methoxy-2-propanol (100 parts by mass based on the total amount of monomers) was added to an empty reaction vessel, followed by heating to 85° C. with stirring. Next, the monomer solution prepared above was added dropwise over 3 hours, followed by further heating at 85° C. for 3 hours. After the completion of the polymerization reaction, the polymerization solution was cooled to room temperature. The cooled polymerization solution was charged into hexane (500 parts by mass based on the polymerization solution), and a precipitated white powder was separated by filtration. The white powder separated by filtration was washed twice with 100 parts by mass of hexane based on the polymerization solution, then separated by filtration, and dissolved in 1-methoxy-2-propanol (300 parts by mass). To this mixture, methanol (500 parts by mass), triethylamine (50 parts by mass) and ultrapure water (10 parts by mass) were added, and a hydrolysis reaction was performed at 70° C. for 6 hours with stirring.

After the completion of the reaction, the remaining solvent was distilled off, and the resulting solid was dissolved in acetone (100 parts by mass). The resulting solution was added dropwise into 500 parts by mass of water to permit the coagulation of the resin. The resulting solid was separated by filtration. The resulting solid was dried at 50° C. for 12 hours to synthesize a white powdery polymer (A-1).

### Polymer Synthesis Examples 2 to 9

Polymers (A-2) to (A-9) were synthesized in the same manner as in Synthesis Example 1 except that the monomer species and the ratio were changed.

### Polymer Synthesis Example 10

A polymer (A-10) was synthesized by performing a polymerization reaction by a known method using a compound (M-10), a compound (M-3), and a compound (M-13).

TABLE 1

| | | Monomer 1 | | Monomer 2 | | Monomer 3 | | | |
|---|---|---|---|---|---|---|---|---|---|
| | | | Amount | | Amount | | Amount | | |
| | | | used | | used | | used | | |
| | Polymer | Type | (mol %) | Type | (mol %) | Type | (mol %) | Mw | Mw/Mn |
| Polymer Synthesis | A-1 | M-1 | 40 | M-3 | 60 | — | — | 5700 | 1.6 |
| Example 1 | | | | | | | | | |
| Polymer Synthesis | A-2 | M-1 | 40 | M-4 | 60 | — | — | 5800 | 1.6 |
| Example 2 | | | | | | | | | |
| Polymer Synthesis | A-3 | M-1 | 30 | M-5 | 60 | M-2 | 10 | 6100 | 1.7 |
| Example 3 | | | | | | | | | |
| Polymer Synthesis | A-4 | M-1 | 40 | M-6 | 60 | — | — | 6200 | 1.5 |
| Example 4 | | | | | | | | | |
| Polymer Synthesis | A-5 | M-1 | 40 | M-7 | 60 | — | — | 5500 | 1.5 |
| Example 5 | | | | | | | | | |
| Polymer Synthesis | A-6 | M-1 | 40 | M-8 | 60 | — | — | 5400 | 1.5 |
| Example 6 | | | | | | | | | |
| Polymer Synthesis | A-7 | M-1 | 40 | M-9 | 60 | — | — | 6000 | 1.7 |
| Example 7 | | | | | | | | | |
| Polymer Synthesis | A-8 | M-1 | 30 | M-3 | 60 | M-10 | 10 | 6900 | 1.7 |
| Example 8 | | | | | | | | | |
| Polymer Synthesis | A-9 | M-1 | 30 | M-3 | 60 | M-11 | 10 | 6800 | 1.7 |
| Example 9 | | | | | | | | | |
| Polymer Synthesis | A-10 | M-12 | 30 | M-3 | 60 | M-13 | 10 | 7100 | 1.7 |
| Example 10 | | | | | | | | | |

### [B] Synthesis of Radiation Sensitive Acid Generator

### Synthesis Example 1 of Radiation Sensitive Acid Generator

### Synthesis of Radiation Sensitive Acid Generator (B-1)

To a reaction vessel, 44 mmol of diphenyl sulfoxide and 480 g of tetrahydrofuran were added. After the mixture was stirred under ice cooling, 134 mmol of chlorotrimethylsilane (TMS-Cl) was added dropwise. Subsequently, a 1 M tetrahydrofuran solution of 134 mmol of a compound represented by the following formula (S-1) was added dropwise. After the mixture was stirred at room temperature for 1 hour, a 2 M aqueous hydrochloric acid solution was added. The aqueous layer was separated and the resulting aqueous layer was washed with diethyl ether. Then, the mixture was separated with dichloromethane to extract the organic layer. After drying over sodium sulfate, the solvent was distilled off. Purification by column chromatography gave a compound (hereinafter, also referred to as “bromide salt (S-2)”) represented by the following formula (S-2).

Then, 26.0 mmol of the bromide salt (S-2), 26.0 mmol of a compound represented by the following formula (P-1) (hereinafter, also referred to as “ammonium salt (P-1)”), 150 g of dichloromethane, and 150 g of ultrapure water were added to a reaction vessel. After stirring at room temperature for 30 minutes, the organic layer was separated. The resulting organic layer was washed with ultrapure water. After drying over anhydrous sodium sulfate, the solvent was distilled off. Purification by column chromatography gave a compound (hereinafter, also referred to as “radiation sensitive acid generator (B-1)”) represented by the following formula (B-1). A synthesis scheme of the radiation sensitive acid generator (B-1) is shown below.

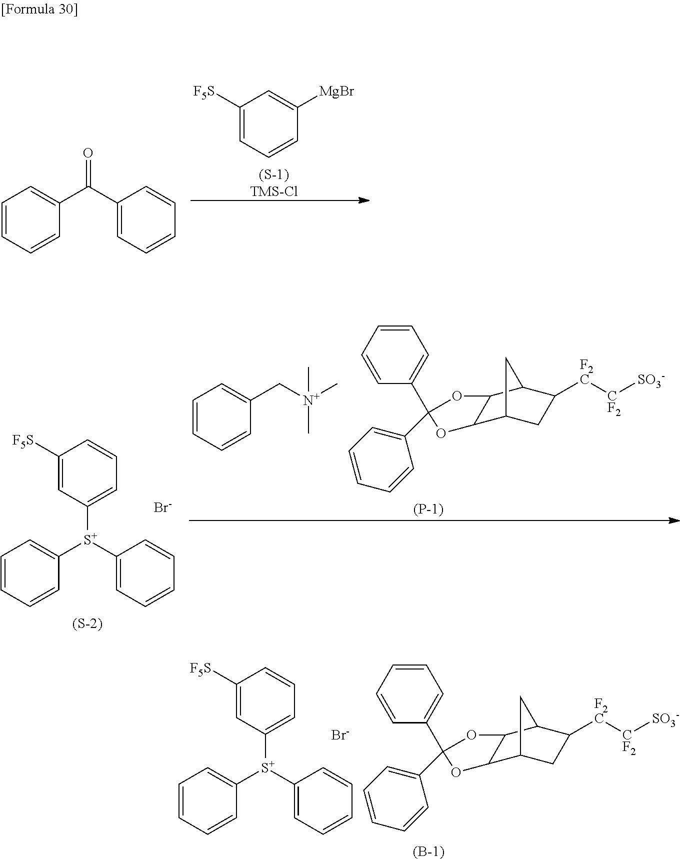

### Synthesis Examples 2 to 4 of Radiation Sensitive Acid Generator

The precursor was appropriately selected, and the same formulation as that in Synthesis Example 1 of the radiation sensitive acid generator was selected to synthesize [B] radiation sensitive acid generators represented by the formulas (B-2) to (B-4).

### Synthesis Example 5 of Radiation Sensitive Acid Generator

### Synthesis of Radiation Sensitive Acid Generator (B-5)

In a reaction vessel, 10.0 mmol of a compound represented by the following formula (S-3), 10.0 mmol of 4-(pentafluorosulfanyl)benzaldehyde, 1.5 mmol of p-toluenesulfonic acid (p-TsOH) and 120 g of toluene were added. A Dean-Stark tube was placed in the reaction vessel, and the solution was stirred under a reflux condition for 8 hours. After the completion of the reaction, a saturated aqueous sodium bicarbonate solution was added, and then dichloromethane was added for extraction. The organic layer was separated, and the separated organic layer was dried over anhydrous sodium sulfate. The solvent was distilled off, and purification by column chromatography gave a compound (hereinafter, also referred to as “radiation sensitive acid generator (B-5)”) represented by the following formula (B-5). A synthesis scheme of the acid generator (B-5) is shown below.

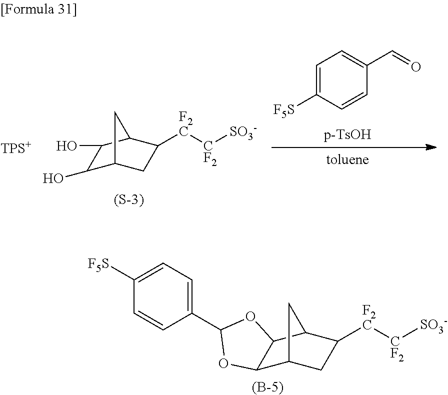

In the synthesis scheme, TPS+ is a triphenylsulfonium cation.

### Synthesis Example 6 of Radiation Sensitive Acid Generator

The precursor was selected, and the same formulation as that in Synthesis Example 5 of the radiation sensitive acid generator was selected to synthesize [B] a radiation sensitive acid generator represented by the formula (B-6).

### Synthesis Example 7 of Radiation Sensitive Acid Generator

### Synthesis of Radiation Sensitive Acid Generator (B-7)

To a reaction vessel, 22.0 mmol of 4-pentafluorosulfanyl benzoyl chloride, 22.0 mmol of a compound represented by the following formula (S-4) and 140 g of tetrahydrofuran were added, followed by stirring. Subsequently, 25.0 mmol of triethylamine and 2.2 mmol of N,N-dimethylaminopyridine were added, followed by stirring at room temperature for 3 hours. After the solvent was distilled off under reduced pressure, a 2 M aqueous hydrochloric acid solution was added, and dichloromethane was further added to separate the organic layer. After the organic layer was dried over anhydrous sodium sulfate, the solvent was distilled off to yield an ester compound. Then, 22.0 mmol of triphenylsulfonium chloride was added to the ester compound, and a mixed solution of water:dichloromethane (1:3 (mass ratio)) was added to yield a 0.5 M solution. After stirring at room temperature for 1 hour, dichloromethane was added for extraction to separate the organic layer. The obtained organic layer was dried over anhydrous sodium sulfate to distill off the solvent. Purification by column chromatography gave the radiation sensitive acid generator represented by the following formula (B-7). A synthesis scheme of the radiation sensitive acid generator (B-7) is shown below.

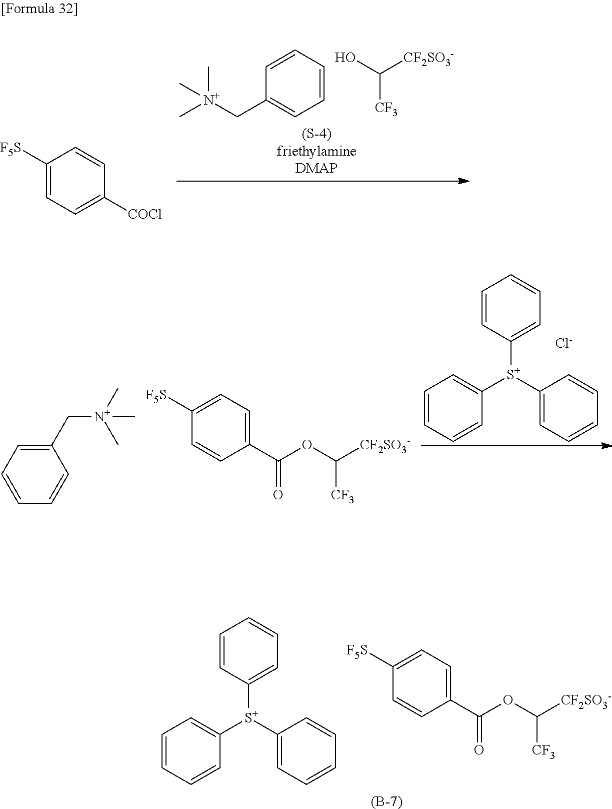

### Synthesis Example 8 of Radiation Sensitive Acid Generator

### Synthesis of Radiation Sensitive Acid Generator (B-8)

To a reaction vessel, 32.0 mmol of 4-pentafluorosulfanyl benzoyl chloride, 35.3 mmol of 4-bromo-3,3,4,4-tetrafluorobutanol and 150 g of tetrahydrofuran were added, followed by stirring under ice cooling. Subsequently, 35.0 mmol of pyridine was added dropwise, followed by stirring at room temperature for 3 hours. After the solvent was distilled off under reduced pressure, a 2 M aqueous hydrochloric acid solution was added, and diethyl ether was further added to separate the organic layer. The organic layer was washed with water twice, then dried over anhydrous sodium sulfate to distill off the solvent. Purification by column chromatography gave a compound represented by the following formula (S-5).

Subsequently, 26.0 mmol of the compound represented by the formula (S-5) was dissolved in a mixed solution of acetonitrile:water (1:1 (mass ratio)) to form a 1 M solution, followed by addition of 52.0 mmol of sodium dithionite and 78.0 mmol of sodium hydrogen carbonate for reaction at 80° C. for 5 hours. After extraction of the reaction product with acetonitrile and subsequent distillation off of the solvent, a mixed solution of acetonitrile:water (3:1 (mass ratio)) was added to form a 0.5 M solution. To this solution, 50.0 mmol of hydrogen peroxide water and 2.9 mmol of sodium tungstate were added, followed by heating and stirring at 50° C. for 7 hours. The reaction product was extracted with acetonitrile, and the solvent was distilled off, to yield a sulfonate salt compound. Then, 26.0 mmol of triphenylsulfonium chloride was added to the sulfonate salt compound, and a mixed solution of water:dichloromethane (1:3 (mass ratio)) was added to yield a 0.5 M solution. After stirring at room temperature for 1 hour, dichloromethane was added for extraction to separate the organic layer. The obtained organic layer was dried over anhydrous sodium sulfate to distill off the solvent. Purification by column chromatography gave the radiation sensitive acid generator represented by the following formula (B-8). A synthesis scheme of the radiation sensitive acid generator (B-8) is shown below.

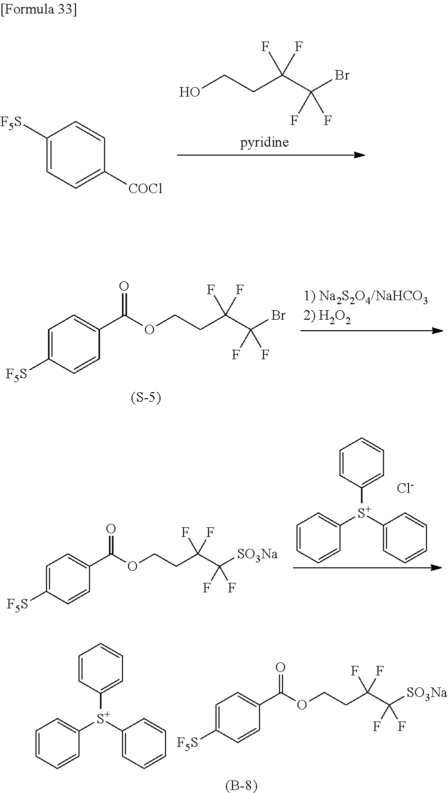

The radiation sensitive acid generators used in the respective Examples and Comparative Examples are shown below.

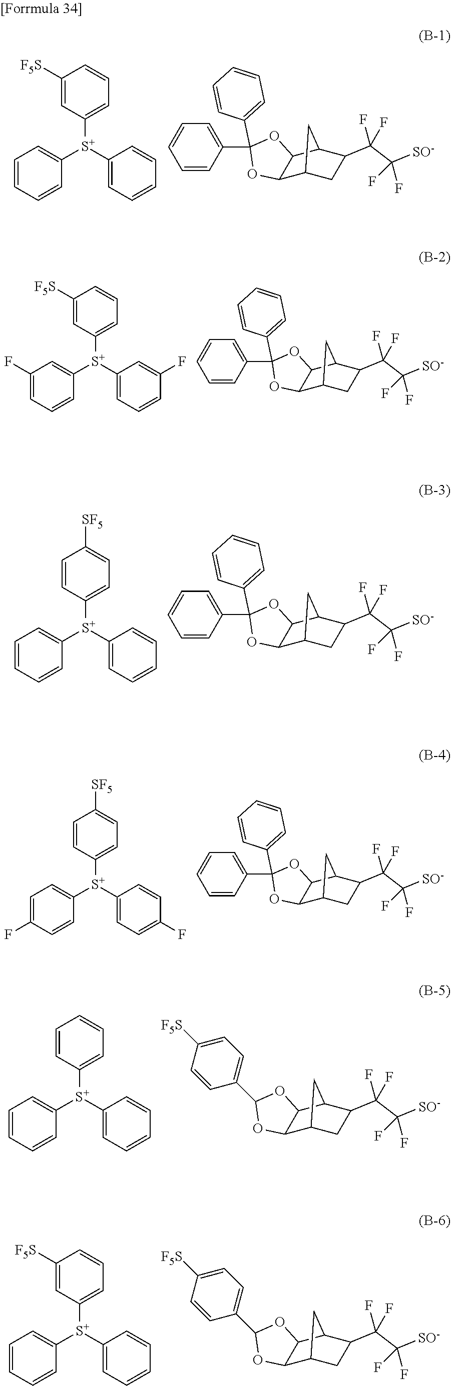

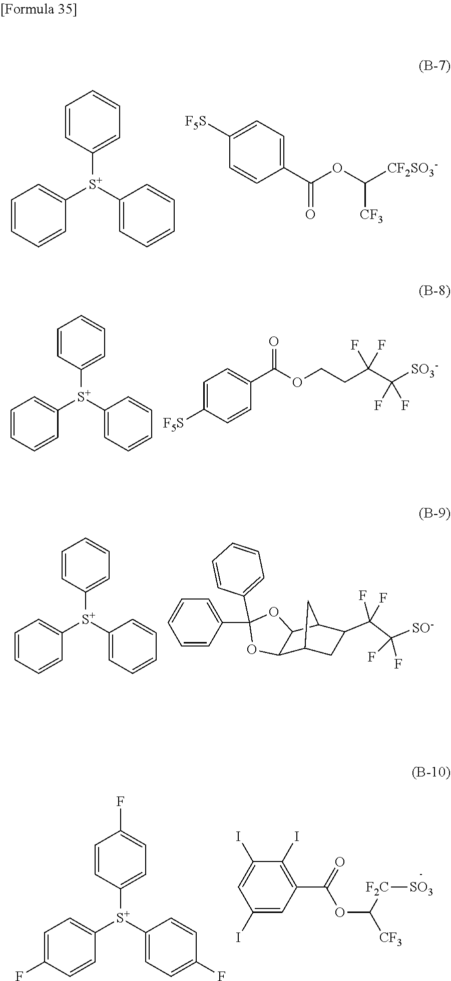

### [D] Synthesis of Acid Diffusion Control Agent

### Synthesis Example 1 of Acid Diffusion Control Agent

### Synthesis of Acid Diffusion Control Agent (D-1)

To a reaction vessel, 5.0 mmol of a compound represented by the following formula (S-2), 5.0 mmol of sodium salicylate, 50 g of dichloromethane and 50 g of ultrapure water were added. After stirring at room temperature for 30 minutes, the organic layer was separated. The obtained organic layer was washed with ultrapure water, and the solvent was distilled off to yield a compound represented by the following formula (D-1) (hereinafter, also referred to as “acid diffusion control agent (D-1)”). A synthesis scheme of the acid diffusion control agent (D-1) is shown below.

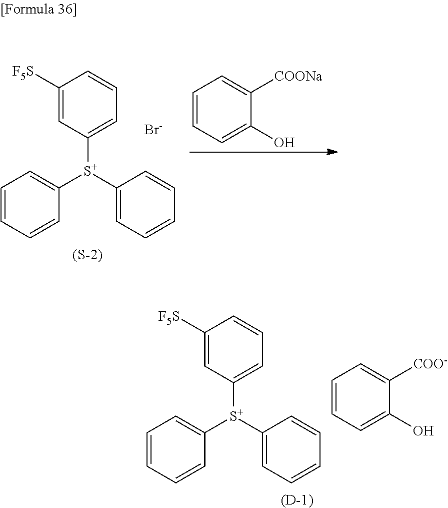

### Synthesis Example 2 of Acid Diffusion Control Agent

The precursor was selected, and the same formulation as that in Synthesis Example 2 of the acid diffusion control agent was selected to synthesize [D] an acid diffusion control agent represented by Formula (D-2).

The acid diffusion control agents used in the respective Examples and Comparative Examples are shown below.

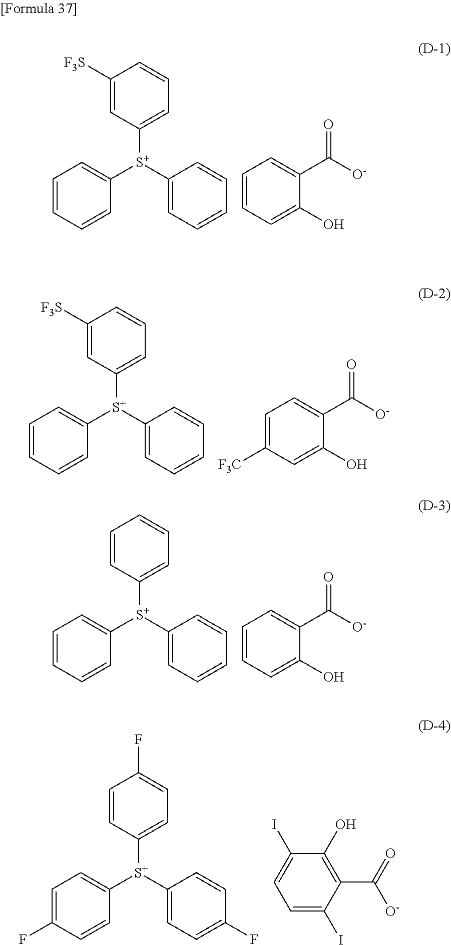

### Example 1

[A]100 parts by mass of the polymer (A-1), [B]20 parts by mass of (B-1) as the radiation sensitive acid generator, [D]20 mol % of (D-3) as the acid diffusion control agent with respect to (B-1), [D]4,800 parts by mass of (E-1) as the organic solvent, and 2,000 parts by mass of (E-2) were mixed, and the resulting mixed solution was filtered through a membrane filter having a pore size of 0.20 μm to prepare a radiation sensitive resin composition (R-1).

### Examples 2 to 24 and Comparative Example 1

Radiation sensitive resin compositions (R-2) to (R-24) and (CR-1) were prepared in the same manner as in Example 1 except that the respective components of the types and the blending amounts shown in the following Table 2 were used.

TABLE 2

| | | | | | | [D] Acid diffusion | | | |
|---|---|---|---|---|---|---|---|---|---|
| | Radiation | [A] Polymer | | [B] Acid generator | | control agent | | [E] Solvent | |
| | sensitive | | Content | | Content | | Content | | Content |
| | resin | | (parts | | (parts | | (parts | | (parts |
| | composition | Type | by mass) | Type | by mass) | Type | by mass) | Type | by mass) |
| Example 1 | R-1 | A-1 | 100 | B-1 | 20 | D-3 | 20 | E-1/E-2 | 4800/2000 |
| Example 2 | R-2 | A-1 | 100 | B-2 | 20 | D-3 | 20 | E-1/E-2 | 4800/2000 |
| Example 3 | R-3 | A-1 | 100 | B-3 | 20 | D-3 | 20 | E-1/E-2 | 4800/2000 |
| Example 4 | R-4 | A-1 | 100 | B-4 | 20 | D-3 | 20 | E-1/E-2 | 4800/2000 |
| Example 5 | R-5 | A-1 | 100 | B-5 | 20 | D-3 | 20 | E-1/E-2 | 4800/2000 |
| Example 6 | R-6 | A-1 | 100 | B-6 | 20 | D-3 | 20 | E-1/E-2 | 4800/2000 |
| Example 7 | R-7 | A-1 | 100 | B-7 | 20 | D-3 | 20 | E-1/E-2 | 4800/2000 |
| Example 8 | R-8 | A-1 | 100 | B-8 | 20 | D-3 | 20 | E-1/E-2 | 4800/2000 |
| Example 9 | R-9 | A-2 | 100 | B-1 | 20 | D-3 | 20 | E-1/E-2 | 4800/2000 |
| Example 10 | R-10 | A-3 | 100 | B-1 | 20 | D-3 | 20 | E-1/E-2 | 4800/2000 |
| Example 11 | R-11 | A-4 | 100 | B-1 | 20 | D-3 | 20 | E-1/E-2 | 4800/2000 |
| Example 12 | R-12 | A-5 | 100 | B-1 | 20 | D-3 | 20 | E-1/E-2 | 4800/2000 |
| Example 13 | R-13 | A-6 | 100 | B-1 | 20 | D-3 | 20 | E-1/E-2 | 4800/2000 |
| Example 14 | R-14 | A-7 | 100 | B-1 | 20 | D-3 | 20 | E-1/E-2 | 4800/2000 |
| Example 15 | R-15 | A-8 | 100 | B-1 | 20 | D-3 | 20 | E-1/E-2 | 4800/2000 |
| Example 16 | R-16 | A-9 | 100 | B-1 | 20 | D-3 | 20 | E-1/E-2 | 4800/2000 |
| Example 17 | R-17 | A-1 | 100 | B-9 | 20 | D-1 | 20 | E-1/E-2 | 4800/2000 |
| Example 18 | R-18 | A-1 | 100 | B-9 | 20 | D-2 | 20 | E-1/E-2 | 4800/2000 |
| Example 19 | R-19 | A-1 | 100 | B-1 | 20 | D-1 | 20 | E-1/E-2 | 4800/2000 |
| Example 20 | R-20 | A-1 | 100 | B-1/B-9 | 15/5 | D-1 | 20 | E-1/E-2 | 4800/2000 |
| Example 21 | R-21 | A-1 | 100 | B-10 | 20 | D-1 | 20 | E-1/E-2 | 4800/2000 |
| Example 22 | R-22 | A-10 | 100 | B-1 | 20 | D-3 | 20 | E-1/E-2 | 4800/2000 |
| Example 23 | R-23 | A-1 | 100 | B-10 | 20 | D-1 | 20 | E-1/E-2 | 4800/2000 |
| Example 24 | R-24 | A-1 | 100 | B-2 | 20 | D-4 | 20 | E-1/E-2 | 4800/2000 |
| Comparative | CR-1 | A-1 | 100 | B-9 | 20 | D-3 | 20 | E-1/E-2 | 4800/2000 |
| Example 1 | | | | | | | | | |

In Table 2, the organic solvents are as follows.
E-1: Propylene glycol monomethyl ether acetate
E-2: Propylene glycol 1-monomethyl ether

### <Formation of Resist Pattern>

Using a spin coater (“CLEAN TRACK ACT 12” manufactured by Tokyo Electron Ltd.), the radiation sensitive resin composition prepared above was applied onto the surface of a 12 inch silicon wafer on which a lower layer film (“AL 412” manufactured by Brewer Science) having an average thickness of 20 nm had been formed. After soft-bake (SB) was performed at 130° C. for 60 seconds, cooling was performed at 23° C. for 30 seconds to form a resist film having an average thickness of 50 nm. Then, the resist film was irradiated with EUV light using an EUV exposure machine (“NXE3300” manufactured by ASML, NA=0.33, lighting condition: Conventional, s=0.89, Mask imecDEFECT32FFR02). The resist film was subjected to post exposure baking (PEB) at 110° C. for 60 seconds. Then, development was performed at 23° C. for 30 seconds using a 2.38% by mass aqueous TMAH solution to form a 32 nm positive line and space pattern.

### <Evaluation>

The LWR performance and process window of the respective radiation sensitive resin compositions were evaluated by measuring the respective resist patterns formed above according to the following method. A scanning electron microscope (“CG-4100” manufactured by Hitachi High-Tech Corporation) was used for measuring the length of the resist pattern. The evaluation results are shown in the following Table 3.

### [Sensitivity]

An exposure amount at which a 32 nm line and space pattern was formed in the formation of the resist pattern was defined as an optimum exposure amount, and the optimum exposure amount was defined as Eop (unit: mJ/cm²). A smaller value of Eop indicates better sensitivity. The sensitivity was evaluated as “A” when the Eop was 30 mJ/cm² or less, “B” when the Eop was more than 30 mJ/cm² and 32 mJ/cm² or less, and “C” when the Eop was more than 32 mJ/cm².

### [LWR Performance]

The formed resist pattern was observed from above using the scanning electron microscope. The line width was measured at a total of 50 points at arbitrary positions. A 3 sigma value was determined from the distribution of the measured values, and defined as LWR (unit: nm). A smaller value of LWR indicates smaller wobble of the line and better LWR performance. The LWR performance was evaluated as “A” when the LWR was 4.0 nm or less, “B” when the LWR was more than 4.0 nm and 4.2 nm or less, and “C” when the LWR was more than 4.2 nm.

### [Process Window]

The “process window” means a range of resist dimensions in which a pattern having no bridge defect or collapse can be formed. A pattern was formed at a low exposure amount to a high exposure amount using a mask forming a 32 nm line and space (1L/1S). Generally, defects such as bridge formation between patterns are observed in the case of low exposure amount, and defects such as pattern collapse are observed in the case of high exposure amount. The difference between the maximum value and the minimum value of the resist dimension in which these defects were not observed was defined as a critical dimension (CD) margin (unit: nm). The CD margin indicates that the larger the value, the wider and better the process window. The CD margin was evaluated as “A” when the CD margin was 30 nm or more, “B” when the CD margin was 28 nm or more and less than 30 nm, and “C” when the CD margin was less than 28 nm.

TABLE 3

| | Radiation sensitive | | LWR | Process |
|---|---|---|---|---|
| | resin composition | Sensitivity | performance | window |
| Example 1 | R-1 | B | B | B |
| Example 2 | R-2 | B | B | B |
| Example 3 | R-3 | B | B | B |
| Example 4 | R-4 | B | B | B |
| Example 5 | R-5 | B | B | B |
| Example 6 | R-6 | B | B | B |
| Example 7 | R-7 | B | B | A |
| Example 8 | R-8 | B | B | A |
| Example 9 | R-9 | B | B | B |
| Example 10 | R-10 | B | B | B |
| Example 11 | R-11 | B | B | B |
| Example 12 | R-12 | B | B | B |
| Example 13 | R-13 | B | B | B |
| Example 14 | R-14 | B | B | B |
| Example 15 | R-15 | B | B | B |
| Example 16 | R-16 | B | B | B |
| Example 17 | R-17 | B | B | B |
| Example 18 | R-18 | B | B | A |
| Example 19 | R-19 | A | B | B |
| Example 20 | R-20 | B | B | B |
| Example 21 | R-21 | B | B | B |
| Example 22 | R-22 | B | A | A |
| Example 23 | R-23 | B | A | A |
| Example 24 | R-24 | B | A | A |
| Comparative | CR-1 | C | C | C |
| Example 1 | | | | |

The evaluation conducted for the resist patterns formed through the EUV exposure revealed that all the radiation sensitive resin compositions of Examples were good in sensitivity, LWR performance, and process window.

### INDUSTRIAL APPLICABILITY

According to the radiation sensitive resin composition, the method for forming a resist pattern, and the like of the present invention, sensitivity, LWR performance, and a process window can be improved as compared with the related art. Therefore, they can be suitably used for the formation of a fine resist pattern in a lithography process for various electronic devices such as semiconductor devices and liquid crystal devices.

1: A radiation sensitive resin composition, comprising:
a resin comprising a repeating unit A which comprises an acid-dissociable group;
an onium salt comprising an organic acid anion moiety and an onium cation moiety; and
a solvent,
wherein the onium salt comprises at least one group selected from the group consisting of a pentafluorosulfanyl group, a pentafluorosulfanyloxy group, and a pentafluorosulfanylthio group.

2: The radiation sensitive resin composition according to claim 1, wherein the onium salt is represented by formula (A-1) or (A-2): 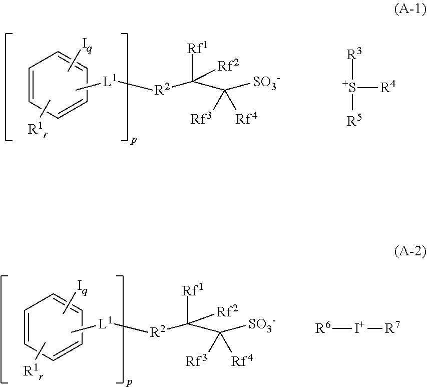
wherein in the formulas (A-1) and (A-2),
L¹ is a single bond, an ether linkage, an ester linkage, or an alkylene group having 1 to 6 carbon atoms optionally comprising an ether linkage or an ester linkage,
R¹ is a hydroxy group, a carboxy group, a fluorine atom, a chlorine atom, a bromine atom, a pentafluorosulfanyl group, a pentafluorosulfanyloxy group, a pentafluorosulfanylthio group, an amino group, —NR⁸—C(═O)—R⁹, —NR⁸—C(═O)—O—R⁹, or a first group which is an alkyl group having 1-20 carbon atoms, an alkoxy group having 1-20 carbon atoms, an alkoxycarbonyl group having 2-10 carbon atoms, an acyloxy group having 2-20 carbon atoms, or an alkylsulfonyloxy group having 1-20 carbon atoms, the first group optionally comprising a fluorine atom, a chlorine atom, a bromine atom, a hydroxy group, an amino group, or an alkoxy group having 1-10 carbon atoms,
R⁸ is a hydrogen atom or an alkyl group having 1 to 6 carbon atoms optionally comprising a halogen atom, a hydroxy group, an alkoxy group having 1 to 6 carbon atoms, an acyl group having 2 to 6 carbon atoms or an acyloxy group having 2 to 6 carbon atoms,
R⁹ is a second group which is an alkyl group having 1 to 16 carbon atoms, an alkenyl group having 2 to 16 carbon atoms, or an aryl group having 6 to 12 carbon atoms, the second group optionally comprising a halogen atom, a hydroxy group, an alkoxy group having 1 to 6 carbon atoms, an acyl group having 2 to 6 carbon atoms, or an acyloxy group having 2 to 6 carbon atoms,
the alkyl group, alkoxy group, alkoxycarbonyl group, acyloxy group, acyl group, and alkenyl group represented by or included in R¹, R⁸, or R⁹ is linear, branched, or cyclic,
R² is a single bond or a linking group having 1 to 20 carbon atoms, which is divalent when p is 1, is a trivalent when p is 2, and is tetravalent when p is 3, the linking group optionally comprising an oxygen atom, a sulfur atom, or a nitrogen atom,
Rf¹ to Rf⁴ are each independently a hydrogen atom, a fluorine atom, or a trifluoromethyl group, at least one of Rf¹ to Rf⁴ being a fluorine atom or a trifluoromethyl group, or Rf¹ and Rf² taken together represent a carbonyl group,
R³, R⁴, R⁵, R⁶, and R⁷ are each independently a monovalent hydrocarbon group having 1 to 20 carbon atoms optionally comprising a hetero atom, and two of R³, R⁴, and R⁵ are optionally bonded to each other to form a ring together with a sulfur atom to which the two of R³, R⁴, and R⁵ are bonded,
p is an integer satisfying 1≤p≤3, and
q and r are integers satisfying 0≤q≤5, 0≤r≤3, and 0≤q+r≤5.

3: The radiation sensitive resin composition according to claim 1, wherein the onium cation moiety is represented by formula (Q-1): 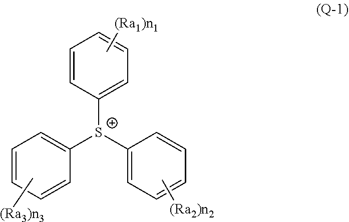
wherein in the formula (Q-1),
Ra₁ and Ra₂ each independently represent a substituent,
n₁ represents an integer of 0 to 5, and when n₁ is 2 or more, a plurality of Ra₁s are same as or different from each other,
n₂ represents an integer of 0 to 5, and when n₂ is 2 or more, a plurality of Ra₂s are same as or different from each other,
n₃ represents an integer of 1 to 5, and when n₃ is 2 or more, a plurality of Ra₃s are same as or different from each other,
Ra₃ represents a substituent, provided that at least one Ra₃ represents a pentafluorosulfanyl group, a pentafluorosulfanyloxy group, or a pentafluorosulfanylthio group,
Ra₁ and Ra₂ are optionally linked to each other to form a ring,
when n₁ is 2 or more, a plurality of Ra₁s are optionally linked to each other to form a ring,
when n₂ is 2 or more, a plurality of Ra₂s are optionally linked to each other to form a ring, and
when n₁ is 1 or more and n₂ is 1 or more, Ra₁ and Ra₂ are optionally linked to each other to form a ring.

4: The radiation sensitive resin composition according to claim 2, wherein in the formula (A-1) or (A-2), r is an integer satisfying 1≤r≤3, and at least one R¹ is a pentafluorosulfanyl group, a pentafluorosulfanyloxy group, or a pentafluorosulfanylthio group.

5: The radiation sensitive resin composition according to claim 1, wherein the onium salt is represented by formula (S-1) or (S-2): 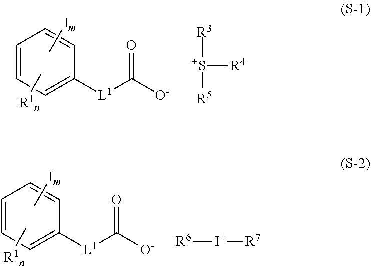
wherein in the formulas (S-1) and (S-2),
R¹ is a hydrogen atom, a hydroxy group, a fluorine atom, a chlorine atom, a bromine atom, a pentafluorosulfanyl group, a pentafluorosulfanyloxy group, a pentafluorosulfanylthio group, an amino group, a nitro group, a cyano group, —NR^{1A}—C(═O)—R^{1B}, —NR^{1A}—C(═O)—O—R^{1B}, or a third group which is an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms, the third group optionally being substituted with a halogen atom,
R^{1A} is a hydrogen atom or an alkyl group having 1 to 6 carbon atoms,
R^{1B} is an alkyl group having 1 to 6 carbon atoms or an alkenyl group having 2 to 8 carbon atoms,
R³, R⁴, R⁵, R⁶, and R⁷ are each independently a monovalent hydrocarbon group having 1 to 20 carbon atoms optionally comprising a hetero atom,
L¹ is a single bond or a divalent linking group having 1 to 20 carbon atoms, optionally comprising an ether linkage, a carbonyl group, an ester linkage, an amide linkage, a sultone ring, a lactam ring, a carbonate linkage, a halogen atom, a hydroxy group, or a carboxy group, and
m and n are integers satisfying 0≤m≤5, 0≤n≤3, and 0≤m+n≤5.

6: The radiation sensitive resin composition according to claim 5, wherein the onium cation moiety is represented by formula (Q-1): 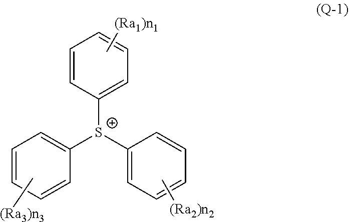
wherein in the formula (Q-1),
Ra₁ and Ra₂ each independently represent a substituent,
n₁ represents an integer of 0 to 5, and when n₁ is 2 or more, a plurality of Ra₁s may be same as or different from each other,
n₂ represents an integer of 0 to 5, and when n₂ is 2 or more, a plurality of Ra₂s are same as or different from each other,
n₃ represents an integer of 1 to 5, and when n₃ is 2 or more, a plurality of Ra₃s are same as or different from each other,
Ra₃ represents a substituent, provided that at least one Ra₃ represents a pentafluorosulfanyl group, a pentafluorosulfanyloxy group, or a pentafluorosulfanylthio group,
Ra₁ and Ra₂ are optionally linked to each other to form a ring,
when n₁ is 2 or more, a plurality of Ra₁s are optionally linked to each other to form a ring,
when n₂ is 2 or more, a plurality of Ra₂s are optionally linked to each other to form a ring, and
when n₁ is 1 or more and n₂ is 1 or more, Ra₁ and Ra₂ are optionally linked to each other to form a ring.

7: The radiation sensitive resin composition according to claim 5, wherein in the formula (S-1) or (S-2), n is an integer satisfying 1≤n≤3, and at least one R¹ is a pentafluorosulfanyl group, a pentafluorosulfanyloxy group, or a pentafluorosulfanylthio group.

8: The radiation sensitive resin composition according to claim 1, wherein the resin comprises a repeating unit D which comprises a phenolic hydroxyl group, and the repeating unit D is represented by formula (D): 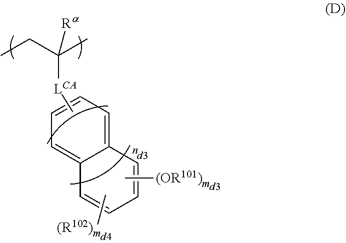
wherein in the formula (D),
R^{α} is a hydrogen atom, a fluorine atom, a methyl group, or a trifluoromethyl group,
L^{CA} is a single bond, —COO—*, or —O—, * is a bond on an aromatic ring side,
R¹⁰¹ is a hydrogen atom or a protective group capable of being deprotected by an action of an acid, when there are a plurality of R¹⁰¹s, the plurality of R¹⁰¹s are same as or different from each other,
R¹⁰² is a cyano group, a nitro group, an alkyl group, a fluorinated alkyl group, an alkoxycarbonyloxy group, an acyl group, or an acyloxy group, and
n_{d3} is an integer of 0 to 2, m_{3d} is an integer of 1 to 8, and m_{d4} is an integer of 1 to 8, provided that 1≤m_{d3}+m_{d4}≤2n_{d3}+5 is satisfied.

9: The radiation sensitive resin composition according to claim 1, wherein the repeating unit A is represented by formula (1): 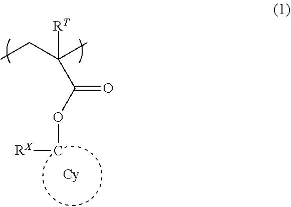
wherein in the formula (1),
R^{T} is a hydrogen atom, a fluorine atom, a methyl group, or a trifluoromethyl group,
R^{X} is a monovalent hydrocarbon group having 1 to 20 carbon atoms, and
Cy represents an alicyclic structure with a 3 to 20 membered ring formed together with the carbon atom to which Cy is bonded.

10: The radiation sensitive resin composition according to claim 1, wherein the resin comprises an iodine-substituted aromatic ring structure.

11: The radiation sensitive resin composition according to claim 2, wherein the organic acid anion moiety comprises an iodine-substituted aromatic ring structure.

12: The radiation sensitive resin composition according to claim 5, wherein the organic acid anion moiety comprises an iodine-substituted aromatic ring structure.

13: A pattern forming method, comprising:
directly or indirectly applying the radiation sensitive resin composition according to claim 1 onto a substrate to form a resist film,
exposing the resist film to light, and
developing the exposed resist film with a developer.

14: The pattern forming method according to claim 13, wherein the exposing is performed using extreme ultraviolet ray or electron beam.

15: A compound comprising
an onium salt which comprises an organic acid anion moiety and an onium cation moiety,
wherein the onium salt comprises at least one group selected from the group consisting of a pentafluorosulfanyl group, a pentafluorosulfanyloxy group, and a pentafluorosulfanylthio group.

16: A radiation sensitive acid generator comprising the compound according to claim 15.

17: An acid diffusion control agent comprising the compound according to claim 15.
